(19) United States
(12) Patent Application Publication
(10) Pub. No.: US 2026/0029449 A1
(43) Pub. Date: Jan. 29, 2026

(54) VAPOR CELL WITH META-SURFACES FOR ELECTROMETRY

(71) Applicant: Honeywell International Inc., Charlotte, NC (US)

(72) Inventors: Argyrios Dellis, Plymouth, MN (US); Chad Fertig, Roseville, MN (US)

(73) Assignee: Honeywell International Inc., Charlotte, NC (US)

(21) Appl. No.: 19/008,372

(22) Filed: Jan. 2, 2025

Related U.S. Application Data
(60) Provisional application No. 63/676,659, filed on Jul. 29, 2024.

(51) Int. Cl. G01R 29/14; H10F 39/90

(52) U.S. Cl. CPC G01R 29/14; H10F 39/90

(57) ABSTRACT

A vapor cell comprises: a main glass body section comprising wall(s) surrounding a cavity, the wall(s) having first interior surface(s) having first glass structures extending into and/or away from the cavity; a top glass lid positioned on top of and attached to the main glass body section, the top glass lid having second interior surface(s) having second glass structures extending into and/or away from the cavity; a bottom glass lid positioned below and attached to the main glass body section, the bottom glass lid having third interior surface(s) having third glass structures extending into and/or away from the cavity; and wherein the first glass structures, the second glass structures, and the third glass structures are configured to tune an index of refraction of the vapor cell to reduce RF signal scattering within the vapor cell.

### CROSS-REFERENCE TO RELATED APPLICATIONS

This application claims the benefit of U.S. Provisional Patent Application Ser. No. 63/676,659 filed on Jul. 29, 2024 and entitled “VAPOR CELL WITH META-SURFACES FOR ELECTROMETRY”, which is hereby incorporated herein by reference in its entirety.

### BACKGROUND

Atomic vapor cells can be used in radio frequency (RF) electrometry, imaging, and communications.

### SUMMARY

A vapor cell comprises: a main glass body section comprising at least one wall surrounding a cavity, the at least one wall having at least a first interior surface having first glass structures extending at least one of into or away from the cavity; a top glass lid positioned on top of and attached to the main glass body section, the top glass lid having at least a second interior surface having second glass structures extending at least one of into or away from the cavity; a bottom glass lid positioned below and attached to the main glass body section, the bottom glass lid having at least a third interior surface having third glass structures extending at least one of into or away from the cavity; and wherein the first glass structures, the second glass structures, and the third glass structures are configured to tune an index of refraction of the vapor cell to reduce RF signal scattering within the vapor cell.

A vapor cell comprises: a main glass body section comprising at least one wall surrounding a cavity, the at least one wall having at least a first interior surface having first glass structures extending at least one of into or away from the cavity; a top glass lid positioned on top of and attached to the main glass body section, the top glass lid having at least a second interior surface having second glass structures extending at least one of into or away from the cavity, wherein the top glass lid is bonded to the main glass body section by at least one of anodic bonding, direct bonding, or eutectic bonding; a bottom glass lid positioned below and attached to the main glass body section, the bottom glass lid having at least a third interior surface having third glass structures extending at least one of into or away from the cavity, wherein the bottom glass lid is bonded to the main glass body section by at least one of anodic bonding, direct bonding, or eutectic bonding; an Alkali reaction chamber positioned within the main glass body section; an Alkali reservoir positioned within the main glass body section; a top photonic integrated circuit (PIC) positioned above the top glass lid, the top PIC interfacing with an input coupling laser and an output probe laser, wherein the top PIC is attached to the top glass lid with optical epoxy; a bottom PIC positioned below the top glass lid, the bottom PIC interfacing with an input probe laser, wherein the bottom PIC is attached to the bottom glass lid with optical epoxy; a top glass positioned above the top PIC, the top glass including at least one top surface having fourth glass structures extending at least one of away from or toward the cavity, wherein the top glass is attached to the top PIC with optical epoxy; a bottom glass positioned below the bottom PIC, the bottom glass including at least one bottom surface having fifth glass structures extending at least one of away from or toward the cavity, wherein the bottom glass is attached to the bottom PIC with optical epoxy; wherein the main glass body section includes at least one outer surface having sixth glass structures extending at least one of away from or toward the cavity; and wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

A vapor cell comprises: a main glass body section comprising: at least a first wall surrounding a first cavity, the at least the first wall having at least a first interior surface having first glass structures extending at least one of into or away from the first cavity; at least a second wall surrounding a second cavity, the at least the second wall having at least a second interior surface having second glass structures extending at least one of into or away from the second cavity; a top glass lid positioned on top of and attached to the main glass body section, the top glass lid having at least a third interior surface having third glass structures extending at least one of into or away from the first cavity and fourth glass structures extending at least one of into or away from the second cavity, wherein the top glass lid is bonded to the main glass body section; a bottom glass lid positioned below and attached to the main glass body section, the bottom glass lid having at least a fourth interior surface having fifth glass structures extending at least one of into or away from the first cavity and sixth glass structures extending at least one of into or away from the second cavity, wherein the bottom glass lid is bonded to the main glass body section; wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

A method of manufacturing a vapor cell comprises: manufacturing a main glass body section comprising at least one wall surrounding a cavity, the at least one wall comprising at least a first interior surface comprising first glass structures extending at least one of into or away from the cavity; manufacturing a top glass lid configured to be positioned on top of and attached to the main glass body section, the top glass lid comprising at least a second interior surface comprising second glass structures configured to extend into the cavity when the top glass lid is positioned on top of the main glass body section; manufacturing a bottom glass lid configured to be positioned below and attached to the main glass body section, the bottom glass lid comprising at least a third interior surface comprising third glass structures configured to extend into the cavity when the bottom glass lid is positioned below the main glass body section; and wherein the first glass structures, the second glass structures, and the third glass structures are configured to tune an index of refraction of the vapor cell to reduce RF signal scattering within the vapor cell.

A method of manufacturing a vapor cell comprises: manufacturing a main glass body section comprising at least one wall surrounding a cavity, an Alkali reaction chamber, and a Alkali reservoir, the at least one wall comprising at least a first interior surface comprising first glass structures extending at least one of into or away from the cavity; manufacturing a top glass lid configured to be positioned on top of an attached to the main glass body section, the top glass lid comprising at least a second interior surface comprising second glass structures configured to extend into the cavity when the top glass lid is positioned on top of the main glass body section; manufacturing a bottom glass lid configured to be positioned below and attached to the main glass body section, the bottom glass lid comprising at least a third interior surface comprising third glass structures configured to extend into the cavity when the bottom glass lid is positioned below the main glass body section; manufacturing a top photonic integrated circuit (PIC); manufacturing a bottom PIC; manufacturing a top glass including at least one top surface comprising fourth glass structures; manufacturing a bottom glass including at least one bottom surface comprising fifth glass structures; manufacturing sixth glass structures extending at least one of away from or toward the cavity onto at least one outer surface of the main glass body section; bonding the bottom glass lid to the main glass body section by at least one of anodic bonding, direct bonding, or eutectic bonding; bonding the top glass lid to the main glass body section by at least one of anodic bonding, direct bonding, or eutectic bonding; attaching the top PIC to the top glass lid with optical epoxy; attaching the bottom PIC to the bottom glass lid with optical epoxy; attaching the top glass to the top PIC with optical epoxy; attaching the bottom glass to the bottom PIC with optical epoxy; and wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

A method of manufacturing a vapor cell comprises: manufacturing a main glass body section comprising at least a first wall surrounding a first cavity and at least a second wall surrounding a second cavity, the at least the first wall comprising at least a first interior surface comprising first glass structures extending at least one of into or away from the first cavity, the at least the second wall comprising at least a second interior surface comprising second glass structures extending at least one of into or away from the second cavity; manufacturing a top glass lid configured to be positioned on top of and attached to the main glass body section, the top glass lid comprising at least a third interior surface comprising third glass structures configured to extend into the first cavity and fourth glass structures configured to extend into the second cavity; manufacturing a bottom glass lid configured to be positioned below and attached to the main glass body section, the bottom glass lid having at least a fourth interior surface comprising fifth glass structures configured to extend into the first cavity and sixth glass structures configured to extend into the second cavity; and wherein the first glass structures, the second glass structures, the third glass structures, the fifth glass structures, and the sixth glass structures are configured to tune an index of refraction of the vapor cell to reduce RF signal scattering within the vapor cell.

### BRIEF DESCRIPTION OF DRAWINGS

Understanding that the drawings depict only exemplary embodiments and are not therefore to be considered limiting in scope, the exemplary embodiments will be described with additional specificity and detail through the use of the accompanying drawings, in which:

FIGS. 1A-1D illustrate an example vapor cell having glass structures extending into a cavity.

FIGS. 2A-2C illustrate an example vapor cell having glass structures extending into a cavity.

FIGS. 3A-3C illustrate an example vapor cell having glass structures extending into a cavity and glass structures extending on the outside of the vapor cell.

FIGS. 4A-4B illustrate example vapor cells with various configurations.

FIG. 5 illustrates an example method for manufacturing a vapor cell including meta-surfaces.

FIG. 6 illustrates an example method of implementing an end-to-end wafer scale process for making all-glass cells having meta-surfaces patterned by SLE and integrated with EPIC chips.

FIG. 7 illustrates an example method of implementing a hybrid process for making all-glass cells having meta-surfaces patterned by SLE and integrated with EPIC chips having a first part wafer scale processing transitioning to a second part die scale processing.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which is shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual steps may be performed. The following detailed description is, therefore, not to be taken in a limiting sense.

In examples, Rydberg based radio frequency (RF) field sensing is a transformative technology for precision metrology used with electronic devices and communications. In examples, Rydberg RF sensors have a potential for ultra-wideband band sensitivity, such as from 100s of megahertz (MHz) to terahertz (THz) with ultra-low Size, Weight, and Power (SWaP) miniature atomic vapor cells. In examples, quantum sensors can detect high frequency electrical fields based on Rydberg atomic vapors. In examples, quantum sensors enable new capabilities in radio frequency (RF) electrometry, imaging, and communications.

In examples, approaches and techniques to alkali vapor cell design and fabrication for electrometry are inadequate for advance receiver applications as they suffer from process variations, poor cell homogeneity, and depressed signal-to-noise ratio (SNR) for detecting submillimeter waves due to the requirement that cell dimensions must be smaller than the sensed wavelength (that is the D<λ restriction) to eliminate deleterious distortions of the field. In examples, these limitations result in limited scope for miniaturization and large-scale production.

In examples, Rydberg RF sensing researchers have identified a number of (sometimes conflicting) requirements that alkali vapor cells should satisfy. In examples, a requirement may be that a vapor cell be constructed of a material with dielectric constant close to unity to minimize scattering and absorption of the RF signal field. In examples, a requirement may be that a vapor cell have a large optically probed volume so that a large number of atoms can be measured, leading to high SNR electromagnetically induced transparency (EIT) spectroscopy. In examples, a requirement may be that a vapor cell have a probed atom volume far from cells walls to reduce wall collision effects which can broaden and shift the EIT resonance energies. In examples, a requirement may be that a vapor cell have an RF scattering cross-section far less than its geometric cross-section. In examples, a requirement may be that a vapor cell exhibit long operational lifetimes, even at high cell temperatures, with no change in spectroscopic properties. In examples, a requirement may be that a vapor cell exhibit no collisional broadening due to contamination by residual background gasses, which may be kept many orders of magnitude below the alkali vapor pressure at its designed operation temperature. In examples, a requirement may be that a vapor cell be configured to control the alkali vapor density by temperature regulation but only using components which do not introduce distortions of the RF signal field. In examples, a requirement may be that a vapor cell be configured to direct the pump and probe fields into the sense volume without introducing optical structures (mirrors, lenses, etc.) which themselves scatter and distort the RF signal field.

In examples, architectures provide scalable and robust methods of vapor cell construction using wafer level processes with manufacturing scalability. In examples, a vapor cell includes directly patterned anti-reflection meta-surface structures. In examples, these anti-reflection meta-surface structures can extend away from the surface or extend into the surface (such as a void or hole). In examples, these meta-surface structures are fabricated with a scalable, wafer-level manufacturing process for robustness and uniformity. In examples, the vapor cells (such as alkali vapor cells) use a specific design and manufacturing process to produce highly uniform cells, utilizing wafer level processing scalable to batch manufacturing, enabling future widespread deployment of quantum sensors using Rydberg spectroscopy.

In examples, three dimensional (3D) meta-surfaces are created using Selective Laser Etching (SLE) (also known as Selective Laser-induced Etching (SLE) or Selective Light Etching (SLE)) enables the use of large volume vapor cells without degraded performance due to radio frequency (RF) reflections. In examples, an Electronic Photonic Integrated Circuit (EPIC) (or other type of Photonic Integrated Circuit (PIC), Photonic Integrated Chip (PIC), or integrated optical circuit) is used to source and collect laser light and electrical signals with minimal RF field distortions.

In examples, the vapor cells (such as alkali vapor cells) are all-glass, anodically bonded, and precision filled with the vapor (such as alkali vapor) under a high vacuum. In examples, the vapor cells (such as alkali vapor cells) may have long operation lifetimes based on the all-glass construction and anodic bond seals. In examples, the vapor cells (such as alkali vapor cells) may have low distortion of RF fields by rubidium drops thanks to a separate rubidium reservoir. In examples, the vapor cells (such as alkali vapor cells) may have zero residual contamination during filling via a multi-chamber precursor process.

In examples, the vapor cells (such as alkali vapor cells) are rapidly and precisely patterned using Selective Laser Etching (SLE). In examples, the vapor cells (such as alkali vapor cells) may have low distortion of RF fields due to reflections and etaloning based on three dimensional (3D) anti-reflection structure (ARS) pattered meta-surfaces on inner and/or outer cell walls. In examples, the vapor cells (such as alkali vapor cells) may allow high SNR EIT spectroscopy, even for millimeter-wave (mm-wave) sensing based on large interaction volumes enabled by broadband ARS patterned surfaces that eliminate reflections. In examples, the vapor cells (such as alkali vapor cells) may have vastly reduced wall interactions even for mm-wave sensing based on large cell dimensions enabled by broadband ARS patterned surfaces.

In examples, the vapor cells (such as alkali vapor cells) use a planar electronic and photonics interface circuit (EPIC) for light routing, beam emission, and optical signal collection. In examples, the vapor cells (such as alkali vapor cells) may have compact and power efficient delivery of multi-wavelength light via an optically contacted photonic circuit layer. In examples, the vapor cells (such as alkali vapor cells) may have delivery of electrical and magnetic control signals using deeply subwavelength traces on the same layer as the photonics. In examples, the vapor cells (such as alkali vapor cells) may have omnidirectional response thanks to ARS being on critical surface, inside and out, since clear optical paths through un-patterned and planar cell windows is not required. In examples, the vapor cells (such as alkali vapor cells) may allow for precision alkali vapor pressure control based on either electrical or all-optical heating.

In examples, wafer-scale approaches to fabricating vapor cells (such as alkali vapor cells) for Rydberg sensors has high sensitivity and accurately detects mm-wave and sub-mm-wave RF signals. In examples, vapor cells (such as alkali vapor cells) made as described herein surpass current technologies of hand-made glass blown cells. In examples, it is challenging to create sub-millimeter dimension vapor cells using glass blown cells. In examples, there are few options for adding subwavelength electrodes and it is problematic to implement broadband RF antireflection functionality. In examples, glass blown cells are not scalable to batch manufacturing. In examples, glass and silicon sandwich cells are limited in the kind and complexity of meta-structures that can be fabricated on the inside and outside of cells, reducing the design space for achieving broadband anti-reflections functionality. In examples, glass and silicon sandwich cells usually occur at the die-level only.

In examples, the deep integration of electronic and photonic circuits into cell design and construction will enable new kinds of multiple-input multiple-output (MIMO) Rydberg sensors with ultra-low SWaP.

In examples, an architecture for vapor cells (such as alkali vapor cells) with meta-surface for electrometry includes a system with all-glass vapor cells and incorporates several complex internal structures that are key to improving the performance of Rydberg sensors. In examples, separate cavities for alkali reservoir and spectroscopy, connected by a thin channel, to reduce the amount of metallic rubidium that adsorbs to the walls of the sense cavity. In examples, the sidewalls have arbitrary internal cross sections, permitting engineered refractive indices to suppress the formation of standing waves. In examples, subwavelength structured meta-surfaces (extending from or into the surface of the sidewalls of the cavity) further suppress u-wave cross section and reflection, reducing field distortion. In examples, micro-optics such as aspheric lenses and light pipes work in concert with the photonics layer to enable efficient light delivery and collection to and from remote optoelectronics.

In examples, wafers of all-glass cells (such as borosilicate, aluminosilicate glass (ASC) to minimize permeation of Helium from and through the glass walls, or a similar glass) are manufactured using Selective Laser Etching/Selective Laser-induced Etching/Selective Light Etching (SLE) fabrication tools and techniques to produce walls with complex cross sections and patterned surfaces used to tune the effective index of refraction and suppress or reduce RF signal distortion or scattering. In examples, SLE enable etching of complex three-dimensional (3D) geometries within glass. In examples, a focused and ultrafast laser rasters (to engrave/etch) over a programmed pattern within glass to enable highly localized enhancement of the glass etch rate. In examples, the glass is then wet-etched with high selectivity (such as 10:1 to 50:1 selectivity for common glasses) to form three-dimensional (3D) features such as voids, think channels, and tall spires, all with a resolution as fine as 1 micrometer (um). In examples, these features can have arbitrary geometries and can be distributed over a substantial portion of inner and outer surfaces of a vapor cell.

In examples, a benefit of engineered three-dimensional (3D) sub-wavelength anti-reflection structures (extending from or into surfaces) includes removing the constraint that cell dimensions of the Rydberg cells must be smaller than the sensed wavelength (that is the D<λ restriction) to be useful for mm-wave detection, thereby permitting large volume cells even for detecting extremely short wavelength signal fields. In examples, the standard approach to fabricating alkali cells suitable for RF signal detection is to reduce the size such that D is substantially less than λ so as to minimize distortions to the RF signal field caused by scattering from the cell body. In examples, when this approach is used in sub-mm-wavelengths, there are increased wall interactions. In examples, when cell dimensions are reduced while laser-atom interaction volume is kept large so as to maintain high SNR, then an ever-larger fraction of the sense volume is perturbed by electric fields coming from charge impurities in the wall surfaces or alkali atoms absorbed on the walls. In examples using the three-dimensional (3D) sub-wavelength anti-reflections structures (extending from or into surfaces), wall interactions are kept insignificant and SNR kept high without necessitating highly elevated cell temperatures and without distortion of the signal field due to standing waves forming in the spectroscopy volume based on the patterned 3D anti-reflection structures (extending from or into surfaces).

In examples, standing mm-waves result in detrimental variation of the amplitude of the E-field. In examples without 3D meta-surfaces, the only known means of eliminating standing waves is to reduce the cell size to below cutoff for unwanted modes. In examples, this solution leads to degradation of the spectroscopy SNR, since small cells require small laser beam diameters, and suffer from amplified effects of atom-wall interactions, leading to broadening and shifting of EIT resonances, as well as a reduction in overall signal size due to fewer proved atoms. In examples, using 3D meta-surfaces on SLE patterned glass cells achieves antireflection properties for RF waves in a manner superior to other methods. In examples, the antireflection functionality of the 3D meta-surfaces does not impose a limitation on operating temperature, unlike deposited coatings or epoxied inserts. In examples, a wide range of refractive index profiles can be engineered using SLE, such that the resulting ARS structures (extending from or into surfaces) are intrinsically broadband.

In examples, meta-surfaces comprised of subwavelength structures (extending from or into surfaces) will be modeled using a high-frequency structure simulator (HFSS), fabricated using SLE, and assessed in a Rydberg spectroscopy testbed. In examples, electrical Rydberg spectroscopy assessments may be used for design, modeling, and testing of the vapor cells with 3D meta-surfaces. In examples, the ARS decorated surfaces create a graded index transaction from free space to glass, reducing the amplitude of scattered and standing waves in the structure. In examples, the meta-structures (extending from or into surfaces) can cover nearly all glass-to-free-space interfaces. In examples, SLE is used to pattern complex internal cavity structures (such as tortious paths) so as to separate a rubidium reservoir and spectroscopy chambers/volumes and to control the flow of alkali vapor.

In examples, micro-optic structures (such as lenses and light-pipes) are patterned into the walls and lids of the all-glass cell for interfacing with a photonics layer delivering the laser light to the vapor. In examples, a wafer scale process is used to construct all-glass cells (such as all-glass cells with a bottom glass lid, glass body, and top glass lid) filled with rubidium and hermetically sealed under high vacuum (such as via anodic bonding, direct bonding, eutectic bonding, etc.). In examples, the ideal vapor cell must be completely evacuated and free of background cases. In examples, a filling method may include depositing precursor chemical(s) (such as Barium Azide (BaN6) and Rubidium Chloride (RbCl)) in the cell (such as by a precision pico-liter dropper) and initiating a reaction (such as by heat or UV light) with the precursor chemical(s) to release the alkali (such as pure rubidium) which deposits on a top glass wafer and is the translated over in vacuum to locate the rubidium over the reservoir chamber, followed by a step to evacuate the unwanted residuals prior to anodic bonding under high vacuum. In examples, this process uses a bonder with an invacuum manipulation stage. In examples, this filling process ensures no contamination of the cells with non-rubidium compounds and also permits precise repeatable control of the amount of alkali filled into cells. In examples, this method is compatible with high volume production and allows for a well-controlled amount of alkali that is deposited in the vapor cell and does not contaminate the vapor cell with residual material.

In examples, anodic bonding affords chemical resistance to long term exposure to alkali vapors as compared to epoxy (which is key to robust operation at elevated temperatures). In examples, anodically bonded cells can withstand temperatures greater than 230° C. and show stable spectroscopy signals for months to years. Unlike epoxy seals, anodic bonds are not attacked by alkalis and the anodic bonding is compatible with high volume, high yield industrial production with shelf lives in excess of 10 years.

In examples, the alkali deposition method has pico-liter resolution (so as to avoid alkali accumulation on the internal surfaces, to reduce charging effects, and to avoid leaving residue (close to or at zero residue) that could change over time and create drift in the complex RF impedance presented by the cell to the detected signal waves). In examples, a top Electronic Photonic Integrated Circuit (EPIC) is attached to the top glass lid and a bottom EPIC is attached to the bottom glass lids. In examples, the top EPIC and the bottom EPIC route probe and coupling lasers to project large, collimated laser beams directly into the vapor without external Gradient Refractive Index (GRIN) lenses. In examples, the top EPIC and the bottom EPIC re-collect light and route it back on fibers for remote detection by active optoelectronics kept far from the EMI sensitive vapor cell. In examples, other photonics (such as photonic beam grating emitters, low loss waveguides, and high efficiency (such as greater than 95% efficient) chip-to-fiber coupler structures for atomic sensors are used to route multiple colors of light to and from the detection volume of the vapor cell with minimal SWaP impact. In examples, an off-resonant NIR laser emitter is used as a nonelectrical heater to control the vapor density in the cell. In examples, the photonics layer can also host deeply subwavelength sized electronic structures (such as electrodes) for direct current (DC), alternating current (AC), and/or radio frequency (RF) excitation.

In examples, cells are entirely glass, comprised of top and bottom SLE patterned cap glass wafers anodically bonded to the SLE patterned body wafer. In examples, glass-to-glass anodic bonding is possible using an interfacial laser of deposited thin films. In examples, two silicon substrates with silicon nitride integrated photonics are attached to the outer surface of the glass lids via optical epoxy to deliver light to and collect light form the vapor cell.

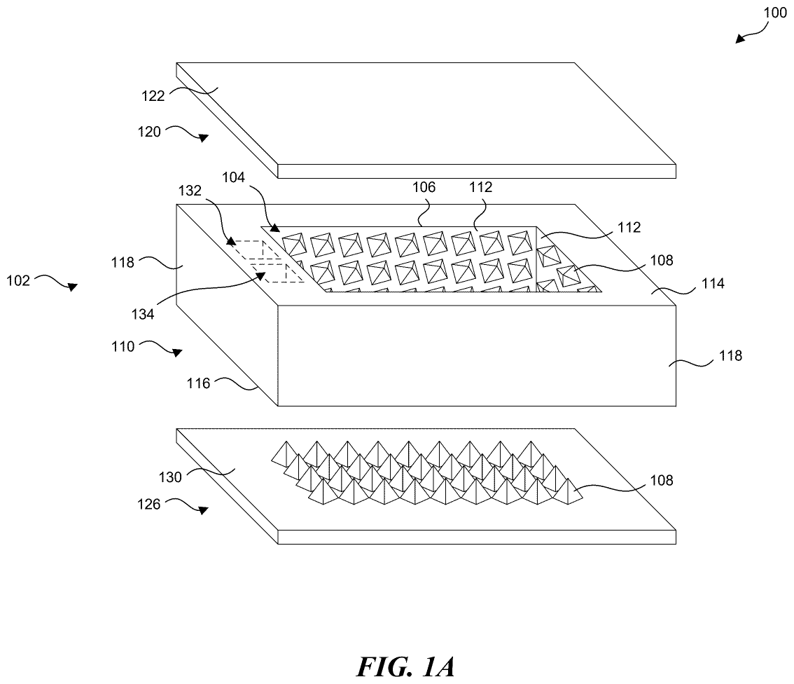

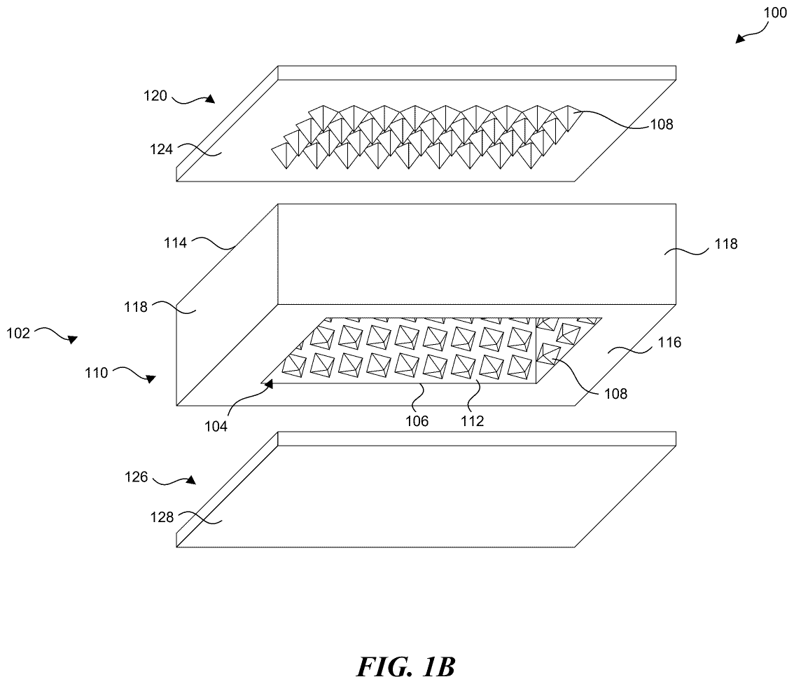

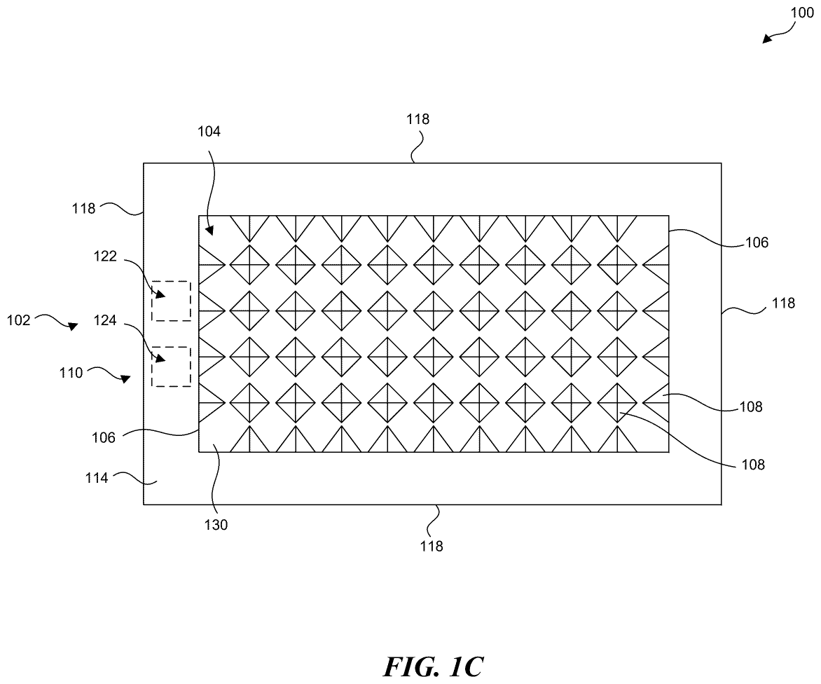

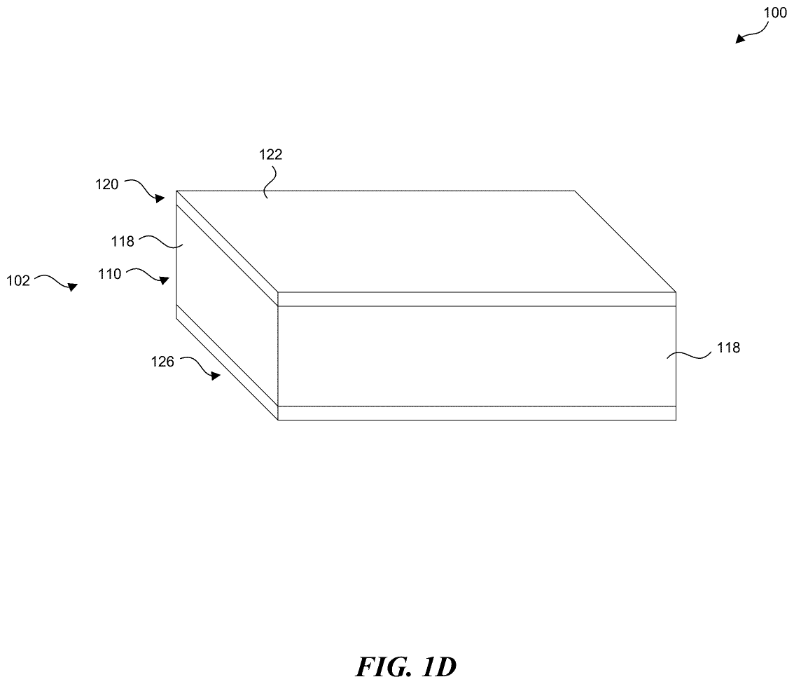

FIGS. 1A-1D illustrate an example vapor cell 100 having glass structures extending into a cavity. While the glass structures in FIGS. 1A-1D are shown extending into the cavity in the embodiments of FIGS. 1A-1D, it is understood that any combination of glass structures that extend from or into surfaces (such as voids or holes) can be used in various embodiments. FIG. 1A shows an exploded top perspective view of components of the vapor cell 100. FIG. 1B shows an exploded bottom perspective view of components of the vapor cell 100. FIG. 1C shows a top view of components of the vapor cell 100. FIG. 1D shows a top perspective view of components of the vapor cell 100. In examples, the vapor cell 100 includes a body 102 having a cavity 104 with at least one interior wall 106 having at least a first cross section configured to tune the effective index of refraction to reduce radio frequency (RF) signal scattering. In examples, the at least one interior wall 106 of the vapor cell 100 includes structures 108 (extending from or into the at least one interior wall 106) used to tune the index of refraction to reduce RF signal scattering. While a single cavity 104 is shown in FIGS. 1A-1D, it is possible that multiple cavities 104 (also referred to as multiple vapor cells) can be combined in a single sensor head and optimized to maximize transmission and minimize distortion in a defined RF frequency band to enable Multiple-Input Multiple-Output (MIMO) architecture.

In examples, the structures 108 are pyramid-shaped and extend from surfaces, though it is understood that the structures 108 may extend into surfaces and may be other shapes and may not be uniform sizes, shapes, or positions. In examples, the shape, size, and positions of the structures 108 (extending from or into surfaces) is selected to attempt to closely match an ideal Klopfenstein index profile. In examples, the height and pitch of the structures 108 (extending from or into surfaces) is varied to achieve better results over the widest possible frequency bands. In examples, optimal geometries are determined to increase transmission |S₂₁|² coefficient from 60% for bare glass to greater than 90% on decorated glass, across two wide frequency bands. In examples operating between 30 GHz and 300 GHz, optimal configuration for the structures 108 (extending from or into surfaces) may be pyramids with a height of 2000 micrometers (μm) and square bases of 500 μm×500 μm. In examples operating between 300 GHz and 800 GHz, optimal configuration for the structures 108 (extending from or into surfaces) may be pyramids with a height of 225 μm and square bases of 75 μm×75 μm. In examples, the structures 108 (extending from or into surfaces) may have simpler geometries or more complicated geometries (such as fractal geometries) that are closer to achieving the ideal Klopfenstein index profile, targeting even flatter response (less than 5%) over even wider frequency bands (such as from 1 GHz to 800 GHz). In examples implementing MIMO with multiple different cavities 104 (multiple vapor cells), the structures 108 (extending from or into surfaces) will likely be configured differently for the different cavities 104 (different vapor cells). More specifically, in examples implementing MIMO with multiple different cavities 104, larger pyramidal structures (extending from or into surfaces) could be used in one cavity 104 for lower mm-wave frequencies while smaller pyramidal structures (right cell) are used to maximize transmission for higher mm-wave frequencies. In examples, only one laser source for the probe beam and one laser source for the coupling beam are required, split and routed by waveguides on EPIC layers (described in more detail below). Examples implementing MIMO with multiple different cavities 104 may have strong common-mode suppression of errors because both the vapor cells share the same alkali reservoir and use the same laser sources for the probe and coupling beams.

In examples, the vapor cell 100 includes a main glass body section 110 having at least one interior wall 106 surrounding the cavity 104. In examples, the at least one interior wall 106 has at least a first interior surface 112. In examples, the at least one interior wall 106 of the main glass body section 110 includes four walls positioned in a rectangular shape and the at least the first interior surface 112 includes four interior surfaces including an interior surface for each of the four walls positioned in the rectangular shape. In other examples, the at least one interior wall 106 surrounding the cavity takes other shapes, such as a circle (with only a single interior surface), square (with four interior surfaces), triangle (with three interior surface, or any other shapes (with any number of interior surfaces). In examples, the at least one interior wall 106 of the main glass body section 110 includes at least one top surface 114, at least one bottom surface 116, and at least one outer surface 118.

In examples, the vapor cell 100 includes a top glass lid 120 positioned on top of the main glass body section 110, the top glass lid 120 having at least a first top surface 122 and at least a second interior surface 124 positioned in toward the cavity 104 and at least partially contacting the at least one top surface 114 of the main glass body section 110. In examples, the vapor cell 100 includes a bottom glass lid 126 positioned below the main glass body section 110, the bottom glass lid 126 having at least a bottom surface 128 and at least a third interior surface 130 positioned in toward the cavity 104 and at least partially contacting the at least one bottom surface 116 of the main glass body section 110. In examples, the at least one of (1) the at least the first interior surface 112, (2) the at least the second interior surface 124, and (3) the at least the third interior surface 130 have the structures 108 (extending from or into surfaces) used to tune the index of refraction to reduce RF signal scattering. In examples, the at least the first interior surface 112 of the at least one interior wall 106 of the main body section has the structures 108 (extending from or into surfaces) used to tune the index of refraction to reduce the RF signal scattering. In examples, the at least the second interior surface 124 of the top glass lid 120 has the structures 108 (extending from or into surfaces) used to tune the index of refraction to reduce the RF signal scattering. In examples, the at least the third interior surface 130 of the bottom glass lid 126 has the structures 108 (extending from or into surfaces) used to tune the index of refraction to reduce the RF signal scattering.

In examples, each of the main glass body section 110, the top glass lid 120, and the bottom glass lid 126 are patterned glass wafers. In examples, each of the main glass body section 110, the top glass lid 120, and the bottom glass lid 126 are patterned using Selective Laser Etching (SLE). In examples, the bottom glass lid 126 is bonded (such as through anodic bonding) to the main glass body section 110. In examples, the top glass lid 120 is bonded (such as through anodic bonding) to the main glass body section 110. In examples, the top glass lid 120 and/or the bottom glass lid 126 are bonded (such as through anodic bonding) to the main glass body section 110. In examples, the main glass body section 110, the top glass lid 120, the bottom glass lid 126, and/or the structures 108 (extending from or into surfaces) are manufactured from glass. In examples, glass-to-glass anodic bonding is performed using an interfacial laser of deposited thin films.

In examples, the vapor cell 100 includes an optional Alkali reaction chamber 132 (or other optional reaction chamber) positioned within the main glass body section 110. In examples, the vapor cell 100 includes an optional Alkali reservoir 134 (or other optional vapor reservoir) positioned within the main glass body section 110. In examples, the Alkali reservoir 134 allows the Alkali (such as metallic rubidium) to be sequestered in a separate reservoir chamber, located remotely from the main spectroscopy chamber where the lasers cross the vapor in the cavity 104. In examples, the Alkali reservoir 134 is connected to the cavity 104 by a tortuous path with a number of turns. In examples, the tortuous path between the Alkali reservoir 134 and the cavity 104 will minimize the impact of metallic rubidium to distort the measured electric field as well as limit the volume of the rubidium adsorbed to the walls of the spectroscopy chamber in the cavity 104. In examples, the tortuous path minimizes the migration of Rb droplets in the beam path and clipping of the laser power.

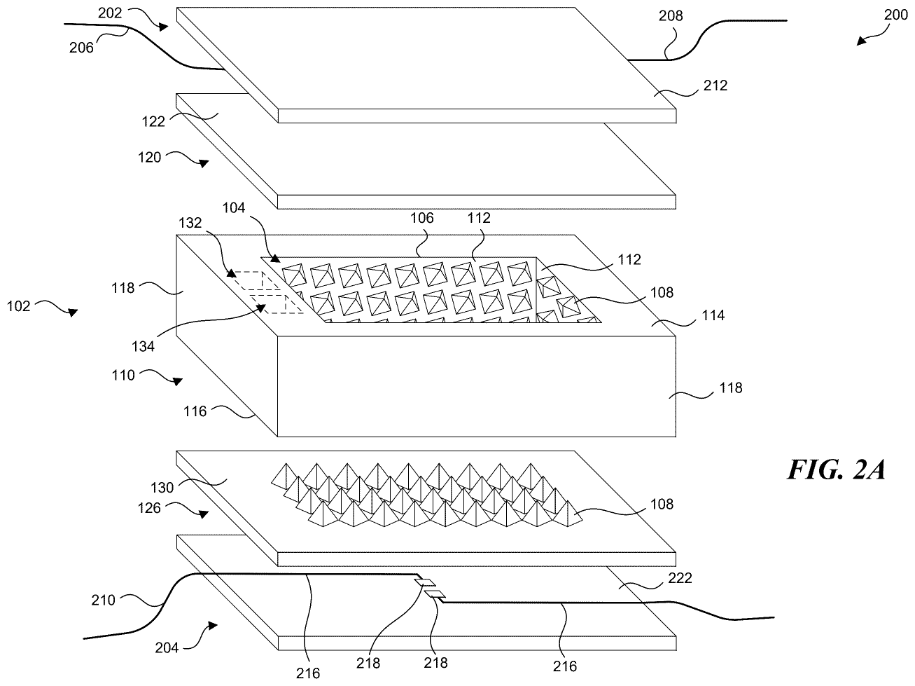

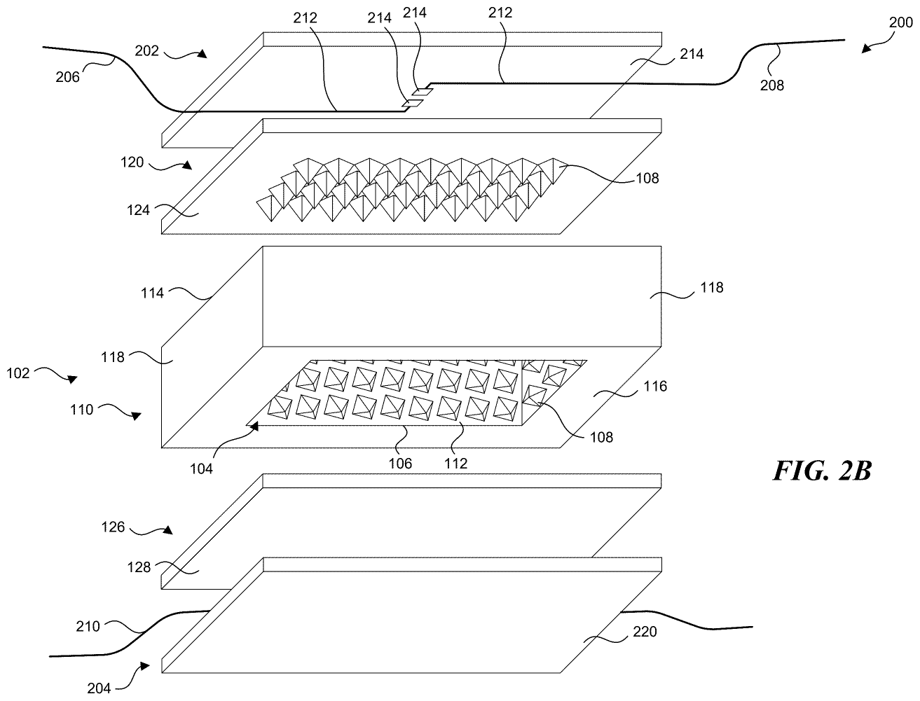

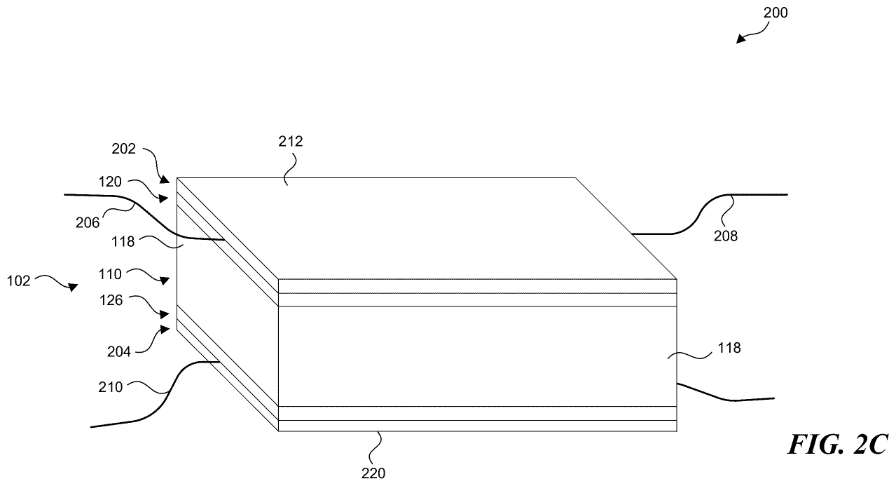

FIGS. 2A-2C illustrate an example vapor cell 200 having glass structures extending into a cavity. While the glass structures in FIGS. 2A-2C are shown extending into the cavity in the embodiments of FIGS. 2A-2C, it is understood that any combination of glass structures that extend from or into surfaces (such as voids or holes) can be used in various embodiments. FIG. 2A shows an exploded top perspective view of components of the vapor cell 200. FIG. 2B shows an exploded bottom perspective view of components of the vapor cell 200. FIG. 2C shows top perspective view of components of the vapor cell 200. In examples, the vapor cell 200 includes features of vapor cell 100 shown in FIGS. 1A-1D and additional features. The references numbers used with reference to vapor cell 100 shown in FIGS. 1A-1D and described above are used in FIGS. 2A-2C for overlapping features.

In examples, a top photonic integrated circuit (PIC) 202 is positioned above the top glass lid 120. In examples, a bottom photonic integrated circuit (PIC) 204 is positioned below the bottom glass lid 126. In examples, the top PIC 202 and the bottom PIC 204 are silicon substrates with silicon nitride integrated photonics. In examples, the top PIC 202 interfaces with an input coupling laser via an optical fiber 206 (such as through fiber ferrules) and an output probe laser via an optical fiber 208 (such as a 780 nm probe beam laser). In examples, the bottom PIC 204 interfaces with an input probe laser via an optical fiber 210 (such as through fiber ferrules). In examples, the top PIC 202 includes at least a top surface 212, at least a bottom surface 214, at least one waveguide 216 (such as a low-loss waveguide), and at least one chip-to-fiber coupler structure 218. In examples, the optical fiber 206 is cemented to the edge of the top PIC 202 and feeds the at least one waveguide 216 which carries light into the center of the top PIC 202 above the cavity 104. In examples, the top PIC 202 delivers the input probe laser beam to the atoms in the cavity 104 through the at least one chip-to-fiber coupler structure 218 (such as a photonic diffractive grating which sends a 1 mm squared collimated beam through the vapor in the cavity 104. In examples, this is done without use of a lens.

In examples, the at least the bottom surface 214 of the top PIC 202 is in at least partial contact with the at least the first top surface 122 of the top glass lid 120. In examples, the at least the bottom surface 214 of the top PIC 202 is attached (such as through optical epoxy) to the at least the first top surface 122 of the top glass lid 120 to deliver light to and collect light from the vapor cell 200. In examples, the bottom PIC 204 includes at least a bottom surface 220, at least a top surface 222, at least one waveguide 224, and at least one chip-to-fiber coupler structure 226. In examples, the at least the top surface 222 of the bottom PIC 204 is in at least partial contact with the bottom surface 128 of the bottom glass lid 126. In examples, the at least the top surface 222 of the bottom PIC 204 is attached (such as through optical epoxy) to the bottom surface 128 of the bottom glass lid 126 to recapture light from the top PIC 202. In examples, the at least one chip-to-fiber coupler structure 226 of the bottom PIC 204 has pattered on it a complementary coupling grating that (with potential assistance of microlenses patterned into the glass via SLE), recaptures the light into a waveguide which is routed to the edge of the chip and then as an output via optical fiber 210. In examples, the bottom PIC 204 delivers coupled light emitted from the grating (such as a 1 mm squared grating) and the gratings are patterned immediately adjacent to one another so that the beams are nearly perfectly counterpropagating.

In examples, both the top PIC 202 and the bottom PIC 204 also contain additional waveguides and emitters for carrying far off resonant infrared (IR) light (such as 1 micron or longer) for the purpose of vapor pressure control via laser heating. In examples of laser heating, the heating laser is absorbed by a color glass filter affixed to the vapor cell 200. In examples, laser heating is the preferred method for controlling the temperature and the density of alkali vapors when electrical heaters should be avoided. In examples of a well thermally isolated vapor cell 200, it is possible to raise the temperature substantially (such as to 150° C. by using only ˜150 mW of optical power). In examples, the top PIC 202 and/or the bottom PIC 204 are also patterned with deeply subwavelength (such as less than 1 μm) conductive metal traces to form coils and electrodes. In examples, these conductive metal traces can be used to apply controlled AC/DC/RF electric and magnetic fields to the vapor in the cavity 104. In examples, background magnetic fields (a source of systematic biases in Rydberg EIT spectroscopy) can be cancelled with metal traces too fine to disturb the RF electric field under measurement. In examples, metal traces on the top PIC 202 or the bottom PIC 204 can also be employed for electrical heating of alkali vapor if laser heating is contraindicated in specific applications.

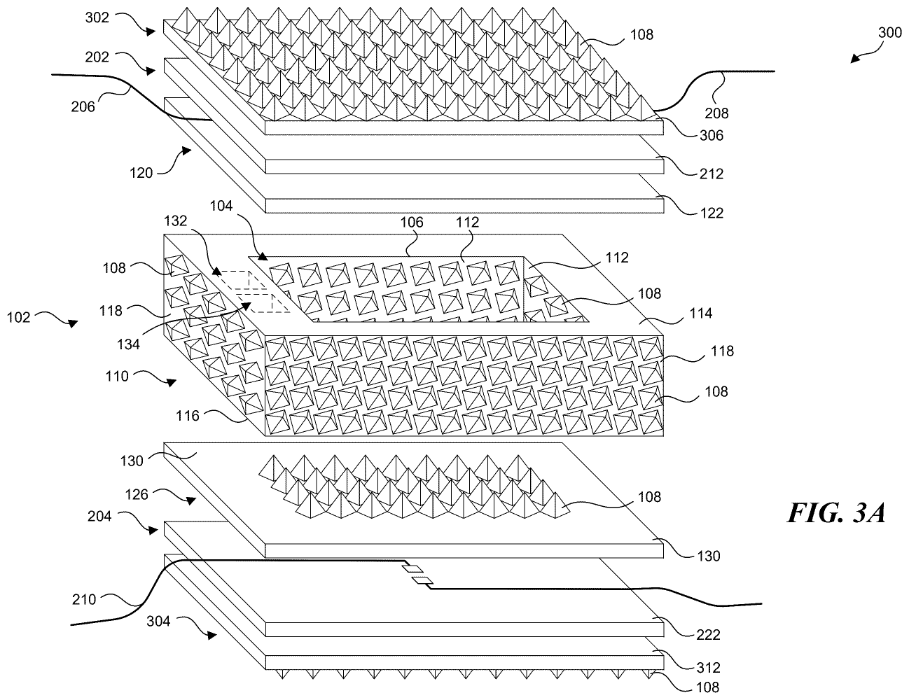

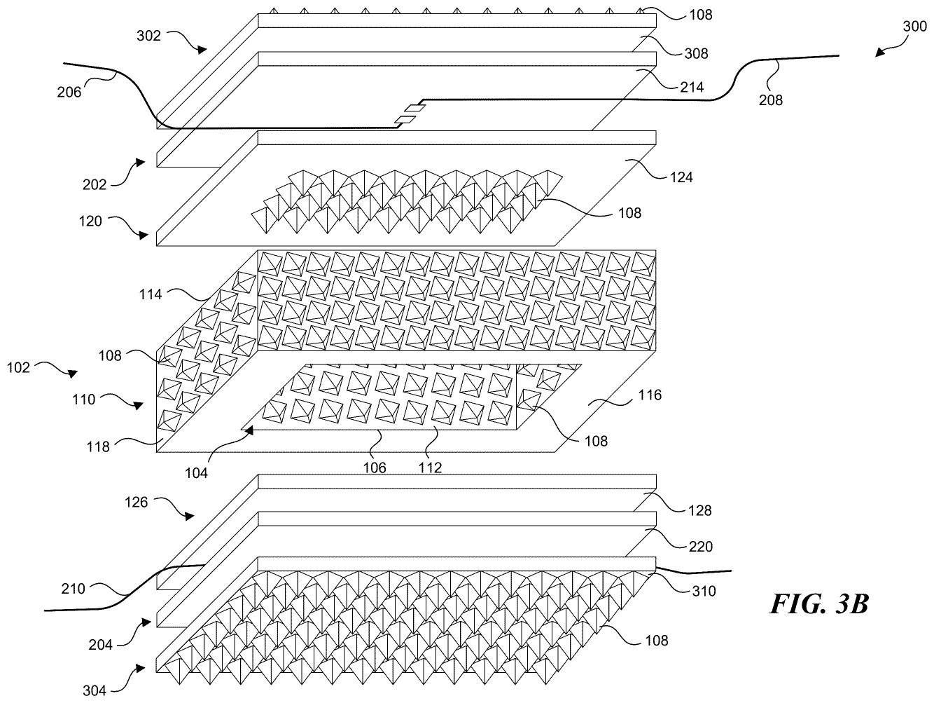

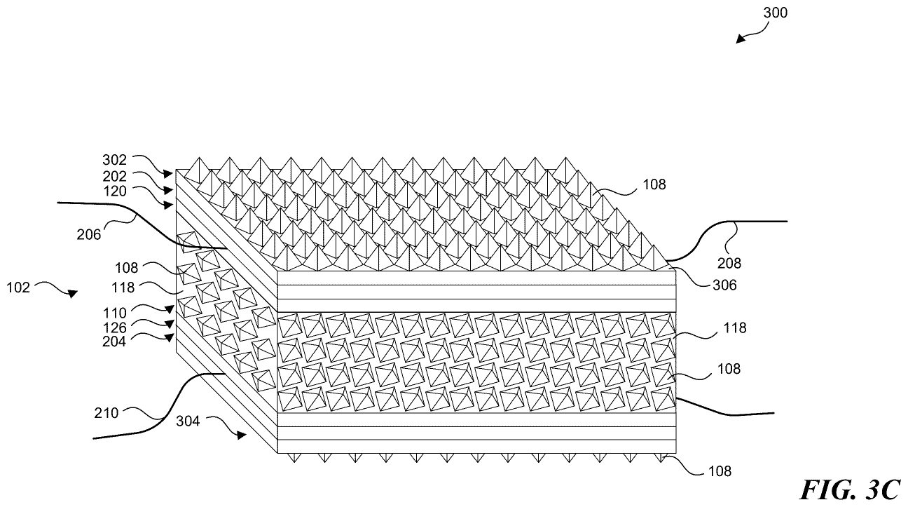

FIGS. 3A-3C illustrate an example vapor cell 300 having glass structures extending into a cavity and glass structures extending on the outside of the vapor cell. While the glass structures in FIGS. 3A-3C are shown extending into the cavity in the embodiments of FIGS. 3A-3C, it is understood that any combination of glass structures that extend from or into surfaces (such as voids or holes) can be used in various embodiments. FIG. 3A shows an exploded top perspective view of components of the vapor cell 300. FIG. 3B shows an exploded bottom perspective view of components of the vapor cell 300. In examples, the vapor cell 300 includes features of vapor cell 100 shown in FIGS. 1A-1D and vapor cell 200 shown in FIGS. 2A-2C and additional features. The reference numbers used with reference to vapor cell 100 shown in FIGS. 1A-1D and vapor cell 200 shown in FIGS. 2A-2C and described above are used in FIGS. 3A-3C for overlapping features.

In examples, a top glass 302 is positioned above the top PIC 202. In examples, a bottom glass 304 is positioned below the bottom PIC 204. In examples, the top glass 302 includes at least a top surface 306 and a bottom surface 308. In examples, the bottom glass 304 includes at least a bottom surface 310 and at least a top surface 312. In examples, at least one of the top surface 306 of the top glass, the bottom surface 310 of the bottom glass 304, and/or the at least one outer surface 118 of the main glass body section 110 includes structures 108 (extending from or into surfaces) used to tune the index of refraction to reduce RF signal scattering.

In examples, the at least the bottom surface 308 of the top glass 302 is in at least partial contact with the top surface 212 of the top PIC 202. In examples, the at least the bottom surface 308 of the top glass 302 is bonded (such as through anodic bonding) to the top surface 212 of the top PIC 202. In examples, the at least the top surface 312 of the bottom glass 304 is in at least partial contact with the bottom surface 220 of the bottom PIC 204. In examples, the at least the top surface 312 of the bottom glass 304 is bonded (such as through anodic bonding) to the bottom surface 220 of the bottom PIC 204.

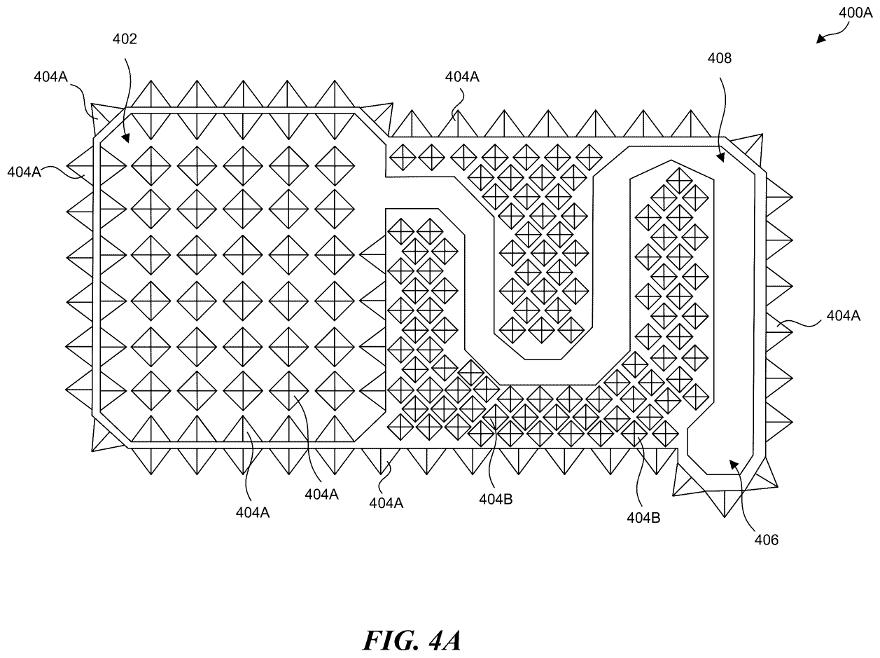

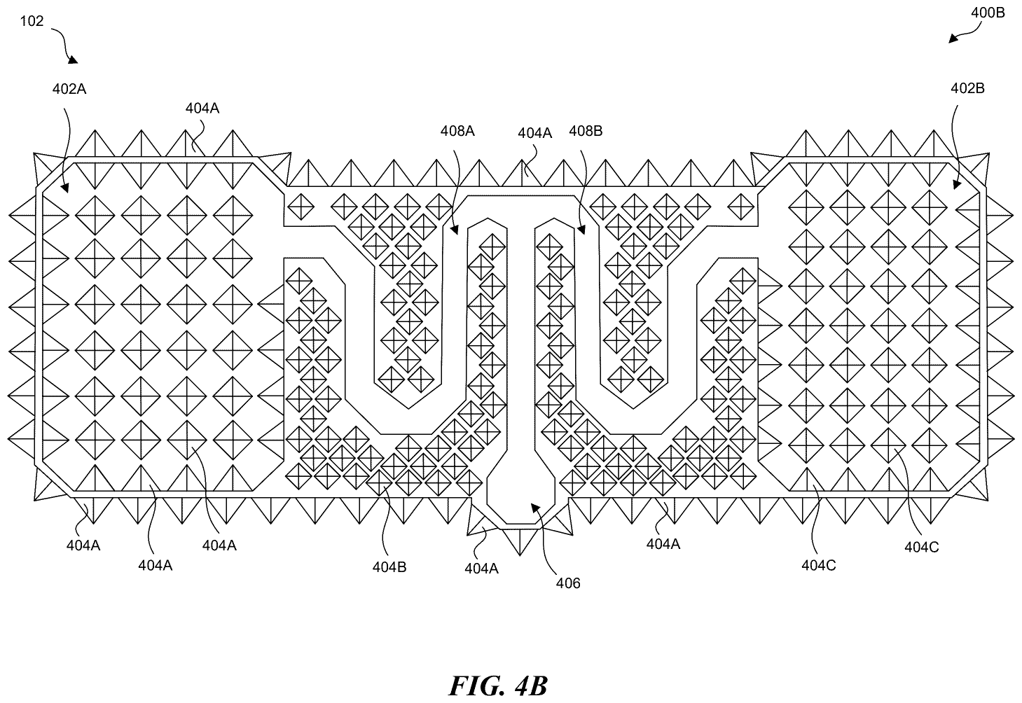

FIGS. 4A-4B illustrate example vapor cells 400A-400B with various configurations. While the glass structures in FIGS. 4A-4B are shown extending into the cavity in the embodiments of FIGS. 4A-4B, it is understood that any combination of glass structures that extend from or into surfaces (such as voids or holes) can be used in various embodiments. FIG. 4A shows a top view of a vapor cell 400A having at least one cavity 402, a plurality of glass structures 404 (extending from or into surfaces, such as glass structures 404A positioned inside the cavity 402 and on the outside of the vapor cell 400A and glass structures 404B positioned in other areas of the vapor cell 400A), at least one alkali reservoir 406, and at least one meandering channel 408. FIG. 4B shows a top view of a vapor cell 400B having a plurality of cavities 402 (including cavity 402A and cavity 402B), a plurality of glass structures 404 (such as glass structures 404A positioned inside the cavity 402A and on the outside of the vapor cell 400B, glass structures 404C positioned inside the cavity 402B, and glass structures 404B positioned in other areas of the vapor cell 400B), at least one alkali reservoir 406, and a plurality of meandering channels 408 (including meandering channel 408A and meandering channel 408B). Each of the features shown in FIGS. 4A-4B can be implemented by features shown in any of FIGS. 1A-1D, 2A-2C, and/or 3A-3C and described above.

As shown in FIGS. 4A and 4B, the glass structures 404A, the glass structures 404B, and/or the glass structures 404C can be different sizes to configure the vapor cell in a desired fashion, such as to suppress the formation of standing waves by reducing the refractive indices using the glass structures 404A, the glass structures 404B, and/or the glass structures 404C). In examples, the at least one separate alkali reservoir 406 is connected to the cavity(s) 402 (such as cavity 400, cavity 402A, and/or cavity 402B) by the meandering channel(s) 408 (such as meandering channel 408, meandering channel 408A, and/or meandering channel 408B). In examples, having a separate cavity 402A and a separate cavity 402B with different sizes/configurations of glass structures 404A and 404C allows for optimization of the separate cavity 402A and separate cavity 402B for different bands (such as cavity 402A being optimized for mid frequency bands and cavity 402B being optimized for high frequency bands, allowing coverage in a broad range, such as from 30 GHz to 800 GHz).

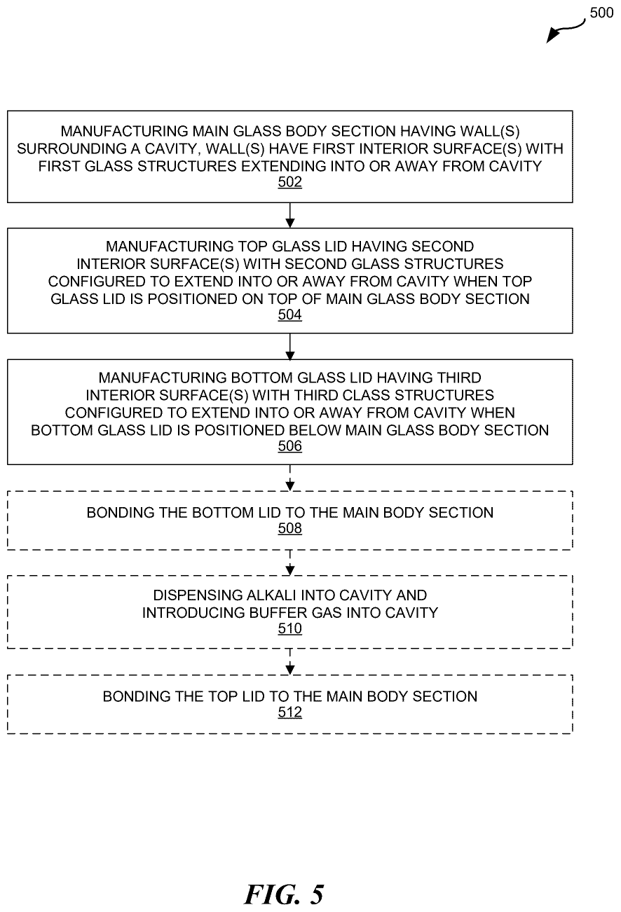

FIG. 5 is an example method 500 for manufacturing a vapor cell including meta-surfaces. In examples, method 500 begins at block 502 with manufacturing a main glass body section having at least one wall surrounding a cavity, the at least one wall having at least a first interior surface having first glass structures extending into or away from the cavity. In examples, an Alkali reaction chamber and/or an Alkali reservoir is manufactured within the main glass body section. In examples, method 500 proceeds to block 504 with manufacturing a top glass lid configured to be positioned on top of and attached to the main glass body section, the top glass lid having at least a second interior surface having second glass structures configured to extend into or away from the cavity when the top glass lid is positioned on top of the main glass body section. In examples, method 500 proceeds to block 506 with manufacturing a bottom glass lid configured to be positioned below and attached to the main glass body section, the bottom glass lid having at least a third interior surface having third glass structures configured to extend into or away from the cavity when the bottom glass lid is positioned below the main glass body section. In examples, the first glass structures, the second glass structures, and the third glass structures are configured to tune an index of refraction of the vapor cell to reduce RF signal scattering within the vapor cell. In examples, manufacturing the main body, manufacturing the top lid, and manufacturing the bottom lid includes selective laser etching (SLE) of glass.

In examples, the method 500 proceeds to optional block 508 with bonding the bottom lid to the main body section (such as by anodic bonding). In examples, the method 500 proceeds to optional block 510 with dispensing alkali into the cavity and introducing buffer gases into the cavity. In examples, the method 500 proceeds to optional block 512 with bonding the top lid to the main body section (such as by anodic bonding). In examples, the at least one wall of the main body section includes four walls positioned in a rectangular shape. In examples, the at least the first interior surface includes four interior surfaces including an interior surface for each of the four walls positioned in the rectangular shape.

In examples, a top photonic integrated circuit (PIC) is manufactured and positioned above the top glass lid. In examples, the top PIC is manufactures from a first silicon substrate. In examples, the top PIC interfaces with an input coupling laser and an output probe laser. In examples, a bottom PIC is manufactured and positioned below the bottom glass lid. In examples, the bottom PIC is manufactured from a second silicon substrate. In examples, the bottom PIC interfaces with an input probe laser. In examples, the top PIC is attached to the top glass lid with optical epoxy. In examples, the bottom PIC is attached to the bottom glass lid with optical epoxy.

In examples, a top glass having fourth glass structures is manufactured and positioned above the top PIC such that the fourth glass structures extend away from the cavity. In examples, the top glass is attached to the top PIC with optical epoxy. In examples, a bottom glass having fifth glass structures is manufactured and positioned below the bottom PIC such that the fifth glass structures extend away from or toward the cavity. In examples, the bottom glass is attached to the bottom PIC with optical epoxy.

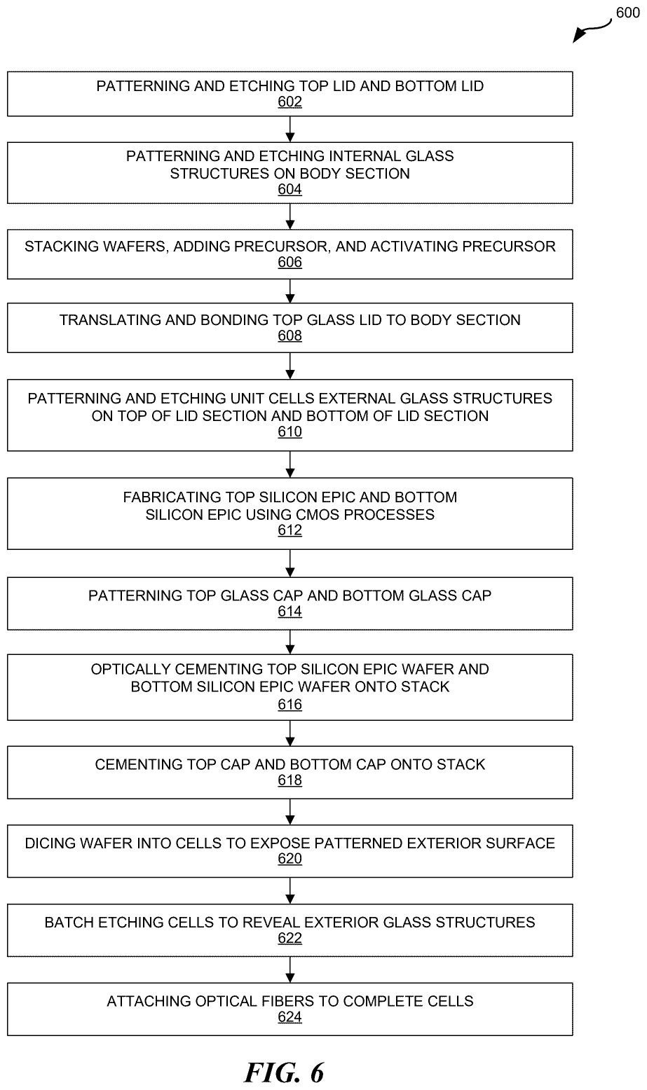

FIG. 6 is a method of implementing an end-to-end wafer scale process for making all-glass cells having meta-surfaces patterned by SLE and integrated with EPIC chips. In examples, method 600 begins at block 602 with patterning and etching (such as by SLE) a top lid and a bottom lid. In examples, method 600 proceeds to block 604 with patterning and etching internal glass structures (extending from or into surfaces) on a body section. In examples, method 600 proceeds to block 606 with stacking the wafers, adding precursor, and activating the precursor. In examples, method 600 proceeds to block 608 with translating and bonding the top glass lid to the body section. In examples, method 600 proceeds to block 610 with patterning and etching (such as by SLE) unit cells with external glass structures (extending from or into surfaces) on the top of the lid section, the bottom of the lid section, and on the body section. In examples, method 600 proceeds to block 612 with fabricating a top silicon Electronic Photonic Integrated Circuit (EPIC) and a bottom silicon EPIC using CMOS processes. In examples, method 600 proceeds to block 614 with patterning (such for subsequent SLE) a top glass cap and a bottom glass cap. In examples, method 600 proceeds with block 616 with optical cementing the top silicon EPIC wafer and the bottom silicon EPIC wafer onto the stack. In examples, method 600 proceeds with block 618 with cementing the top cap and the bottom cap onto the stack. In examples, method 600 proceeds with block 620 with dicing the wafer into cells, exposing the pattered (such as by SLE) exterior surface.

In examples, method 600 proceeds with block 622 with batch etching the cells to reveal the exterior glass structures (extending from or into surfaces). In examples, method 600 proceeds with block 624 with attaching optical fibers to complete the cells.

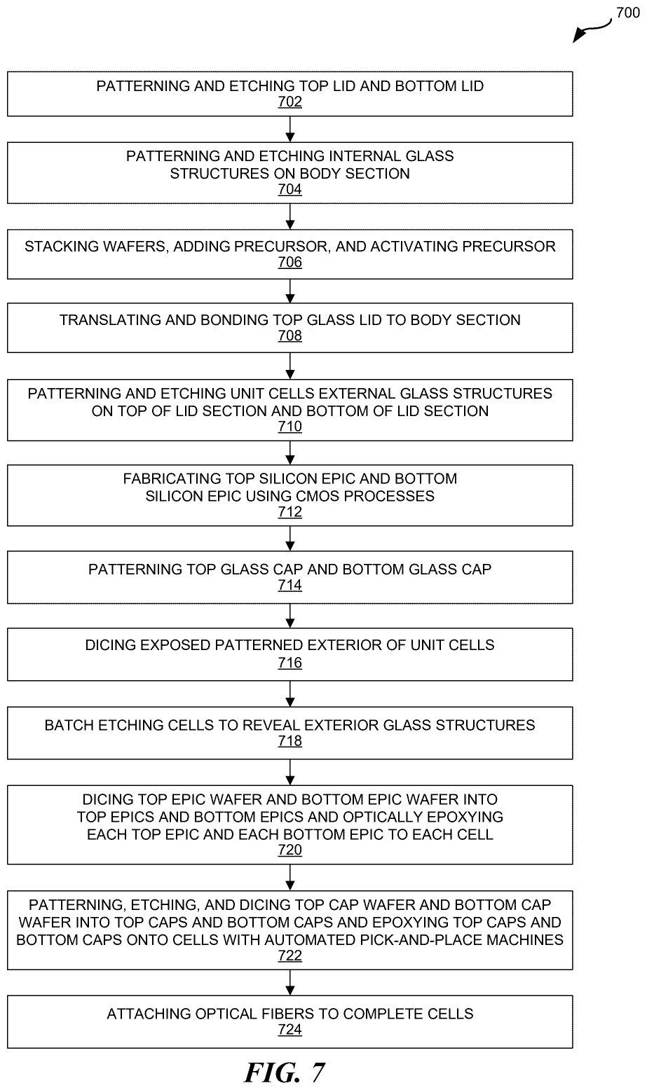

FIG. 7 is a method of implementing a hybrid process for making all-glass cells having meta-surfaces patterned by SLE and integrated with EPIC chips having a first part wafer scale processing transitioning to a second part die scale processing. In examples, method 700 begins at block 702 with patterning and etching (such as by SLE) a top lid and a bottom lid. In examples, method 700 proceeds to block 704 with patterning and etching internal glass structures (extending from or into surfaces) on a body section. In examples, method 700 proceeds to block 706 with stacking the wafers, adding precursor, and activating the precursor. In examples, method 700 proceeds to block 708 with translating and bonding the top glass lid to the body section. In examples, method 700 proceeds to block 710 with patterning and etching (such as by SLE) external glass structures (extending from or into surfaces) on the top of the lid section, the bottom of the lid section, and on the body section. In examples, method 700 proceeds to block 712 with fabricating a top silicon Electronic Photonic Integrated Circuit (EPIC) and a bottom silicon EPIC using CMOS processes. In examples, method 700 proceeds to block 714 with patterning (such for subsequent SLE) a top glass cap and a bottom glass cap. In examples, method 700 proceeds with block 716 with dicing exposed SLE patterned exterior of unit cells. In examples, method 700 proceeds with block 718 with batch etching the cells to reveal exterior glass structures (extending from or into surfaces). In examples, method 700 proceeds with block 720 with dicing the top EPIC wafer and the bottom EPIC wafer into top EPICs and bottom EPICs and optically epoxying each top EPIC and each bottom EPIC to each cell. In examples, method 700 proceeds with block 722 with patterning, etching (such as by SLE), and dicing the top cap wafer and the bottom cap wafer into top caps and bottom caps and then epoxying the top caps and the bottom caps onto the cells with automated pick-and-place machines. In examples, method 700 proceeds with block 724 with attaching optical fibers to complete the cells.

While detailed descriptions of one or more embodiments of the disclosure have been given above, various alternatives, modifications, and equivalents will be apparent to those skilled in the art without varying from the spirit of the disclosure.

For example, while the embodiments described above refer to particular features, the scope of this disclosure also includes embodiments having different combinations of features and embodiments that do not include all of the described features. Accordingly, the scope of the present disclosure is intended to embrace all such alternatives, modifications, and variations as fall within the scope of the claims, together with all equivalents thereof. Therefore, the above description should not be taken as limiting.

### EXAMPLES

Example 1 includes a vapor cell, comprising: a main glass body section comprising at least one wall surrounding a cavity, the at least one wall having at least a first interior surface having first glass structures extending at least one of into or away from the cavity; a top glass lid positioned on top of and attached to the main glass body section, the top glass lid having at least a second interior surface having second glass structures extending at least one of into or away from the cavity; a bottom glass lid positioned below and attached to the main glass body section, the bottom glass lid having at least a third interior surface having third glass structures extending at least one of into or away from the cavity; and wherein the first glass structures, the second glass structures, and the third glass structures are configured to tune an index of refraction of the vapor cell to reduce RF signal scattering within the vapor cell.

Example 2 includes the vapor cell of Example 1, wherein at least a first glass structure of the first glass structures extends from the at least the first interior surface of the at least one wall and into the cavity; wherein at least a second glass structure of the second glass structures extends from the at least the second interior surface of the top glass lid and into the cavity; and wherein at least a third glass structure of the third glass structures extends from the at least the third interior surface of the bottom glass lid and into the cavity.

Example 3 includes the vapor cell of any of Examples 1-2, wherein at least a first glass structure of the first glass structures extends away from the cavity as a void into the at least the first interior surface of the at least one wall; wherein at least a second glass structure of the second glass structures extends away from the cavity as a void into the at least the second interior surface of the top glass lid; and wherein at least a third glass structure of the third glass structures extends away from the cavity as a void into the at least the third interior surface of the bottom glass lid.

Example 4 includes the vapor cell of any of Examples 1-3, wherein the bottom glass lid is bonded to the main glass body section by at least one of anodic bonding, direct bonding, or eutectic bonding; and wherein the top glass lid is bonded to the main glass body section by at least one of anodic bonding, direct bonding, or eutectic bonding.

Example 5 includes the vapor cell of any of Examples 1-4, further comprising: wherein the at least one wall of the main glass body section includes four walls positioned in a rectangular shape; and wherein the at least the first interior surface includes four interior surfaces including an interior surface for each of the four walls positioned in the rectangular shape.

Example 6 includes the vapor cell of any of Examples 1-5, further comprising: an Alkali reaction chamber positioned within the main glass body section; an Alkali reservoir positioned within the main glass body section; a top photonic integrated circuit (PIC) positioned above the top glass lid, the top PIC interfacing with an input coupling laser, an output probe laser, and at least a first photodiode; and a bottom PIC positioned below the bottom glass lid, the bottom PIC interfacing with an input probe laser and at least a second photodiode.

Example 7 includes the vapor cell of Example 6, further comprising: wherein the top glass lid is bonded to the main glass body section by at least one of anodic bonding, direct bonding, or eutectic bonding; wherein the bottom glass lid is bonded to the main glass body section by at least one of anodic bonding, direct bonding, or eutectic bonding; wherein the top PIC is attached to the top glass lid with optical epoxy; and wherein the bottom PIC is attached to the bottom glass lid with optical epoxy.

Example 8 includes the vapor cell of any of Examples 1-7, further comprising: an Alkali reaction chamber positioned within the main glass body section; an Alkali reservoir positioned within the main glass body section; a top photonic integrated circuit (PIC) positioned above the top glass lid, the top PIC interfacing with an input coupling laser and an output probe laser; a bottom PIC positioned below the bottom glass lid, the bottom PIC interfacing with an input probe laser; a top glass positioned above the top PIC, the top glass including at least one top surface having fourth glass structures extending at least one of away from or toward the cavity; a bottom glass positioned below the bottom PIC, the bottom glass including at least one bottom surface having fifth glass structures extending at least one of away from or toward the cavity; wherein the main glass body section includes at least one outer surface having sixth glass structures extending at least one of away from or toward the cavity; and wherein the fourth glass structures, the fifth glass structures, and the sixth glass structures are configured to tune the index of refraction of the vapor cell to reduce the RF signal scattering within the vapor cell.

Example 9 includes the vapor cell of Example 8, further comprising: wherein the top glass lid is bonded to the main glass body section by at least one of anodic bonding, direct bonding, or eutectic bonding; wherein the bottom glass lid is bonded to the main glass body section by at least one of anodic bonding, direct bonding, or eutectic bonding; wherein the top PIC is attached to the top glass lid with optical epoxy; wherein the bottom PIC is attached to the bottom glass lid with optical epoxy; wherein the top glass is attached to the top PIC with optical epoxy; and wherein the bottom glass is attached to the bottom PIC with optical epoxy.

Example 10 includes the vapor cell of any of Examples 1-9, further comprising: wherein the main glass body section further comprises at least a second wall surrounding a second cavity, the at least the second wall having at least a fourth interior surface having fourth glass structures extending at least one of into or away from the second cavity; wherein the at least the second interior surface of the top glass lid has fifth glass structures extending at least one of into or away from the second cavity; wherein the at least the third interior surface of the bottom glass lid has sixth glass structures extending at least one of into or away from the second cavity; and wherein the fourth glass structures, the fifth glass structures, and the sixth glass structures are configured to tune the index of refraction of the vapor cell to reduce the RF signal scattering within the vapor cell.

Example 11 includes the vapor cell of Example 10, further comprising: at least one Alkali reaction chamber positioned within the main glass body section; at least one Alkali reservoir positioned within the main glass body section; a top photonic integrated circuit (PIC) positioned above the top glass lid, the top PIC interfacing with an input coupling laser and an output probe laser; a bottom PIC positioned below the bottom glass lid, the bottom PIC interfacing with an input probe laser; a top glass positioned above the top PIC, the top glass including at least one top surface having seventh glass structures extending at least one of away from or toward the cavity and the second cavity; a bottom glass positioned below the bottom PIC, the bottom glass including at least one bottom surface having eighth glass structures extending at least one of away from or toward the cavity and the second cavity; wherein the main glass body section includes at least one outer surface having ninth glass structures extending at least one of away from or toward the cavity; and wherein the seventh glass structures, the eighth glass structures, and the ninth glass structures are configured to tune the index of refraction of the vapor cell to reduce the RF signal scattering within the vapor cell.

Example 12 includes the vapor cell of Example 11, further comprising: at least one meandering channel connecting the at least one Alkali reaction chamber, the at least one Alkali reservoir, the first cavity, and the second cavity.

Example 13 includes a vapor cell, comprising: a main glass body section comprising at least one wall surrounding a cavity, the at least one wall having at least a first interior surface having first glass structures extending at least one of into or away from the cavity; a top glass lid positioned on top of and attached to the main glass body section, the top glass lid having at least a second interior surface having second glass structures extending at least one of into or away from the cavity, wherein the top glass lid is bonded to the main glass body section by at least one of anodic bonding, direct bonding, or eutectic bonding; a bottom glass lid positioned below and attached to the main glass body section, the bottom glass lid having at least a third interior surface having third glass structures extending at least one of into or away from the cavity, wherein the bottom glass lid is bonded to the main glass body section by at least one of anodic bonding, direct bonding, or eutectic bonding; an Alkali reaction chamber positioned within the main glass body section; an Alkali reservoir positioned within the main glass body section; a top photonic integrated circuit (PIC) positioned above the top glass lid, the top PIC interfacing with an input coupling laser and an output probe laser, wherein the top PIC is attached to the top glass lid with optical epoxy; a bottom PIC positioned below the top glass lid, the bottom PIC interfacing with an input probe laser, wherein the bottom PIC is attached to the bottom glass lid with optical epoxy; a top glass positioned above the top PIC, the top glass including at least one top surface having fourth glass structures extending at least one of away from or toward the cavity, wherein the top glass is attached to the top PIC with optical epoxy; a bottom glass positioned below the bottom PIC, the bottom glass including at least one bottom surface having fifth glass structures extending at least one of away from or toward the cavity, wherein the bottom glass is attached to the bottom PIC with optical epoxy; wherein the main glass body section includes at least one outer surface having sixth glass structures extending at least one of away from or toward the cavity; and wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

Example 14 includes the vapor cell of Example 13, wherein at least a first glass structure of the first glass structures extends from the at least the first interior surface of the at least one wall and into the cavity; wherein at least a second glass structure of the second glass structures extends from the at least the second interior surface of the top glass lid and into the cavity; wherein at least a third glass structure of the third glass structures extends from the at least the third interior surface of the bottom glass lid and into the cavity; wherein at least a fourth glass structure of the fourth glass structures extends from the at least one top surface of the top glass away from the cavity; and wherein at least a fifth glass structure of the fifth glass structures extends from the at least one bottom surface of the bottom glass away from the cavity.

Example 15 includes the vapor cell of any of Examples 13-14, wherein at least a first glass structure of the first glass structures extends away from the cavity as a void into the at least the first interior surface of the at least one wall; wherein at least a second glass structure of the second glass structures extends away from the cavity as a void into the at least the second interior surface of the top glass lid; wherein at least a third glass structure of the third glass structures extends away from the cavity as a void into the at least the third interior surface of the bottom glass lid; wherein at least a fourth glass structure of the fourth glass structures extends toward the cavity as a void into the at least one top surface of the top glass; and wherein at least a fifth glass structure of the fifth glass structures extends toward the cavity as a void into the at least one bottom surface of the bottom glass.

Example 16 includes the vapor cell of any of Examples 13-15, further comprising: wherein the main glass body section further comprises at least a second wall surrounding a second cavity, the at least the second wall having at least a fourth interior surface having seventh glass structures extending at least one of into or away from the second cavity; wherein the at least the second interior surface of the top glass lid has eighth glass structures extending at least one of into or away from the second cavity; wherein the at least the third interior surface of the bottom glass lid has ninth glass structures extending at least one of into or away from the second cavity; wherein the third glass structures, the fourth glass structures, and the ninth glass structures are configured to tune the index of refraction of the vapor cell to reduce the RF signal scattering within the vapor cell.

Example 17 includes a vapor cell, comprising: a main glass body section comprising: at least a first wall surrounding a first cavity, the at least the first wall having at least a first interior surface having first glass structures extending at least one of into or away from the first cavity; at least a second wall surrounding a second cavity, the at least the second wall having at least a second interior surface having second glass structures extending at least one of into or away from the second cavity; a top glass lid positioned on top of and attached to the main glass body section, the top glass lid having at least a third interior surface having third glass structures extending at least one of into or away from the first cavity and fourth glass structures extending at least one of into or away from the second cavity, wherein the top glass lid is bonded to the main glass body section; a bottom glass lid positioned below and attached to the main glass body section, the bottom glass lid having at least a fourth interior surface having fifth glass structures extending at least one of into or away from the first cavity and sixth glass structures extending at least one of into or away from the second cavity, wherein the bottom glass lid is bonded to the main glass body section; wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

Example 18 includes the vapor cell of Example 17, wherein at least a first glass structure of the first glass structures extends from the at least the first interior surface of the at least the first wall and into the first cavity; wherein at least a second glass structure of the second glass structures extends from the at least the second interior surface of the at least the second wall and into the second cavity; wherein at least a third glass structure of the third glass structures extends from the at least the third interior surface of the top glass lid and into the first cavity; wherein at least a fourth glass structure of the fourth glass structures extends from the at least the third interior surface of the top glass lid and into the second cavity; wherein at least a fifth glass structure of the fifth glass structures extends from the at least the fourth interior surface of the bottom glass lid and into the first cavity; and wherein at least a sixth glass structure of the sixth glass structures extends from the at least the fourth interior surface of the bottom glass lid and into the second cavity.

Example 19 includes the vapor cell of any of Examples 17-18, further comprising: an Alkali reaction chamber positioned within the main glass body section; an Alkali reservoir positioned within the main glass body section; a top photonic integrated circuit (PIC) positioned above the top glass lid, the top PIC interfacing with an input coupling laser and an output probe laser; a bottom PIC positioned below the bottom glass lid, the bottom PIC interfacing with an input probe laser; wherein the top PIC is attached to the top glass lid with optical epoxy; and wherein the bottom PIC is attached to the bottom glass lid with optical epoxy.

Example 20 includes the vapor cell of Example 19, further comprising: a top glass positioned above the top PIC, the top glass including at least one top surface having seventh glass structures extending at least one of away from or toward the first cavity and the second cavity; a bottom glass positioned below the bottom PIC, the bottom glass including at least one bottom surface having eighth glass structures extending at least one of away from or toward the first cavity and the second cavity; wherein the main glass body section includes at least one outer surface having ninth glass structures extending at least one of away from or toward the first cavity and the second cavity; and wherein the seventh glass structures, the eighth glass structures, and the ninth glass structures are configured to tune the index of refraction of the vapor cell to reduce the RF signal scattering within the vapor cell.

Example 21 includes a method of manufacturing a vapor cell, the method comprising: manufacturing a main glass body section comprising at least one wall surrounding a cavity, the at least one wall comprising at least a first interior surface comprising first glass structures extending at least one of into or away from the cavity; manufacturing a top glass lid configured to be positioned on top of and attached to the main glass body section, the top glass lid comprising at least a second interior surface comprising second glass structures configured to extend into the cavity when the top glass lid is positioned on top of the main glass body section; manufacturing a bottom glass lid configured to be positioned below and attached to the main glass body section, the bottom glass lid comprising at least a third interior surface comprising third glass structures configured to extend into the cavity when the bottom glass lid is positioned below the main glass body section; and wherein the first glass structures, the second glass structures, and the third glass structures are configured to tune an index of refraction of the vapor cell to reduce RF signal scattering within the vapor cell.

Example 22 includes the method of Example 21, wherein manufacturing the main glass body section comprises manufacturing at least a first glass structure of the first glass structures to extend from the at least the first interior surface of the at least one wall and into the cavity; wherein manufacturing the top glass lid comprises manufacturing at least a second glass structure of the second glass structures to extend from the at least the second interior surface of the top glass lid and into the cavity; and wherein manufacturing the bottom glass lid comprises manufacturing at least a third glass structure of the third glass structures to extend from the at least the third interior surface of the bottom glass lid and into the cavity.

Example 23 includes the method of any of Examples 21-22, wherein manufacturing the main glass body section comprises manufacturing at least a first glass structure of the first glass structures to extend away from the cavity as a void into the at least the first interior surface of the at least one wall; wherein manufacturing the top glass lid comprises manufacturing at least a second glass structure of the second glass structures to extend away from the cavity as a void into the at least the second interior surface of the top glass lid; and wherein manufacturing the bottom glass lid comprises manufacturing at least a third glass structure of the third glass structures to extend away from the cavity as a void into the at least the third interior surface of the bottom glass lid.

Example 24 includes the method of any of Examples 21-23, wherein manufacturing the main glass body section, manufacturing the top glass lid, and manufacturing the bottom glass lid includes selective laser etching (SLE) of glass.

Example 25 includes the method of any of Examples 21-24, further comprising: bonding the bottom glass lid to the main glass body section by at least one of anodic bonding, direct bonding, or eutectic bonding; and bonding the top glass lid to the main glass body section by at least one of anodic bonding, direct bonding, or eutectic bonding.

Example 26 includes the method of any of Examples 21-25, further comprising: wherein the at least one wall of the main glass body section includes four walls positioned in a rectangular shape; and wherein the at least the first interior surface includes four interior surfaces including an interior surface for each of the four walls positioned in the rectangular shape.

Example 27 includes the method of any of Examples 21-26, further comprising: manufacturing an Alkali reaction chamber within the main glass body section; manufacturing an Alkali reservoir within the main glass body section; manufacturing a top photonic integrated circuit (PIC); positioning the top PIC above the top glass lid to interface with an input coupling laser and an output probe laser; manufacturing a bottom PIC; and positioning the bottom PIC below the bottom glass lid to interface with an input probe laser.

Example 28 includes the method of Example 27, further comprising: bonding the bottom glass lid to the main glass body section by anodic bonding; bonding the top glass lid to the main glass body section by anodic bonding; attaching the top PIC to the top glass lid with optical epoxy; and attaching the bottom PIC to the bottom glass lid with optical epoxy.

Example 29 includes the method of any of Examples 21-28, further comprising: manufacturing an Alkali reaction chamber within the main glass body section; manufacturing an Alkali reservoir within the main glass body section; manufacturing a top photonic integrated circuit (PIC); positioning the top PIC above the top glass lid to interface with an input coupling laser and an output probe laser; manufacturing a bottom PIC; positioning the bottom PIC below the bottom glass lid to interface with an input probe laser; manufacturing a top glass including at least one top surface comprising fourth glass structures; positioning the top glass above the top PIC such that the fourth glass structures extend away from the cavity; manufacturing a bottom glass including at least one bottom surface comprising fifth glass structures;

positioning the bottom glass below the bottom PIC such that the fifth glass structures extend away from the cavity; and wherein the fourth glass structures and the fifth glass structures are configured to tune the index of refraction of the vapor cell to reduce the RF signal scattering within the vapor cell.

Example 30 includes the method of Example 29, further comprising: bonding the bottom glass lid to the main glass body section by anodic bonding; bonding the top glass lid to the main glass body section by anodic bonding; attaching the top PIC to the top glass lid with optical epoxy; attaching the bottom PIC to the bottom glass lid with optical epoxy; attaching the top glass to the top PIC with optical epoxy; and attaching the bottom glass to the bottom PIC with optical epoxy.

Example 31 includes the method of any of Examples 21-30, further comprising: wherein the main glass body section further comprises at least a second wall surrounding a second cavity, the at least the second wall comprising at least a fourth interior surface comprising fourth glass structures extending at least one of into or away from the second cavity; wherein the at least the second interior surface of the top glass lid comprises fifth glass structures extending at least one of into or away from the second cavity; wherein the at least the third interior surface of the bottom glass lid comprises sixth glass structures extending at least one of into or away from the second cavity; and wherein the fourth glass structures, the fifth glass structures, and the sixth glass structures are configured to tune the index of refraction of the vapor cell to reduce the RF signal scattering within the vapor cell.

Example 32 includes the method of any of Examples 21-31, further comprising: manufacturing an Alkali reaction chamber within the main glass body section; manufacturing an Alkali reservoir within the main glass body section; manufacturing a top photonic integrated circuit (PIC); positioning the top PIC above the top glass lid to interface with an input coupling laser and an output probe laser; manufacturing a bottom PIC; positioning the bottom PIC below the bottom glass lid to interface with an input probe laser; manufacturing a top glass including at least one top surface comprising fourth glass structures; positioning the top glass above the top PIC such that the fourth glass structures extend away from the cavity; manufacturing a bottom glass including at least one bottom surface comprising fifth glass structures; positioning the bottom glass below the bottom PIC such that the fifth glass structures extend away from the cavity; and wherein the fourth glass structures and the fifth glass structures are configured to tune the index of refraction of the vapor cell to reduce the RF signal scattering within the vapor cell.

Example 33 includes the method of Example 32, further comprising: bonding the bottom glass lid to the main glass body section by anodic bonding; bonding the top glass lid to the main glass body section by anodic bonding; attaching the top PIC to the top glass lid with optical epoxy; attaching the bottom PIC to the bottom glass lid with optical epoxy; attaching the top glass to the top PIC with optical epoxy; and attaching the bottom glass to the bottom PIC with optical epoxy.

Example 34 includes a method of manufacturing a vapor cell, the method comprising: manufacturing a main glass body section comprising at least one wall surrounding a cavity, an Alkali reaction chamber, and a Alkali reservoir, the at least one wall comprising at least a first interior surface comprising first glass structures extending at least one of into or away from the cavity; manufacturing a top glass lid configured to be positioned on top of an attached to the main glass body section, the top glass lid comprising at least a second interior surface comprising second glass structures configured to extend into the cavity when the top glass lid is positioned on top of the main glass body section; manufacturing a bottom glass lid configured to be positioned below and attached to the main glass body section, the bottom glass lid comprising at least a third interior surface comprising third glass structures configured to extend into the cavity when the bottom glass lid is positioned below the main glass body section; manufacturing a top photonic integrated circuit (PIC); manufacturing a bottom PIC; manufacturing a top glass including at least one top surface comprising fourth glass structures; manufacturing a bottom glass including at least one bottom surface comprising fifth glass structures; manufacturing sixth glass structures extending at least one of away from or toward the cavity onto at least one outer surface of the main glass body section; bonding the bottom glass lid to the main glass body section by at least one of anodic bonding, direct bonding, or eutectic bonding; bonding the top glass lid to the main glass body section by at least one of anodic bonding, direct bonding, or eutectic bonding; attaching the top PIC to the top glass lid with optical epoxy; attaching the bottom PIC to the bottom glass lid with optical epoxy; attaching the top glass to the top PIC with optical epoxy; attaching the bottom glass to the bottom PIC with optical epoxy; and wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

Example 35 includes the method of Example 34, wherein manufacturing the main glass body section comprises manufacturing at least a first glass structure of the first glass structures to extend from the at least the first interior surface of the at least one wall and into the cavity; wherein manufacturing the top glass lid comprises manufacturing at least a second glass structure of the second glass structures to extend from the at least the second interior surface of the top glass lid and into the cavity; wherein manufacturing the bottom glass lid comprises manufacturing at least a third glass structure of the third glass structures to extend from the at least the third interior surface of the bottom glass lid and into the cavity; wherein manufacturing the top glass comprises manufacturing at least a fourth glass structure of the fourth glass structures to extend from the at least one top surface of the top glass away from the cavity; and wherein manufacturing the bottom glass lid comprises manufacturing at least a fifth glass structure of the fifth glass structures to extend from the at least one bottom surface of the bottom glass away from the cavity.

Example 36 includes the method of any of Examples 34-35, further comprising: wherein the main glass body section further comprises at least a second wall surrounding a second cavity, the at least the second wall comprising at least a fourth interior surface comprising seventh glass structures extending at least one of into or away from the second cavity; wherein the at least the second interior surface of the top glass comprises eighth glass structures extending at least one of into or away from the second cavity; wherein the at least the third interior surface of the bottom glass comprises ninth glass structures extending at least one of into or away from the second cavity; and wherein the seventh glass structures, the eighth glass structures, and the ninth glass structures are configured to tune the index of refraction of the vapor cell to reduce the RF signal scattering within the vapor cell.

Example 37 includes a method of manufacturing a vapor cell, the method comprising: manufacturing a main glass body section comprising at least a first wall surrounding a first cavity and at least a second wall surrounding a second cavity, the at least the first wall comprising at least a first interior surface comprising first glass structures extending at least one of into or away from the first cavity, the at least the second wall comprising at least a second interior surface comprising second glass structures extending at least one of into or away from the second cavity; manufacturing a top glass lid configured to be positioned on top of and attached to the main glass body section, the top glass lid comprising at least a third interior surface comprising third glass structures configured to extend into the first cavity and fourth glass structures configured to extend into the second cavity; manufacturing a bottom glass lid configured to be positioned below and attached to the main glass body section, the bottom glass lid having at least a fourth interior surface comprising fifth glass structures configured to extend into the first cavity and sixth glass structures configured to extend into the second cavity; and wherein the first glass structures, the second glass structures, the third glass structures, the fifth glass structures, and the sixth glass structures are configured to tune an index of refraction of the vapor cell to reduce RF signal scattering within the vapor cell.

Example 38 includes the method of Example 37, wherein manufacturing the main glass body section comprises manufacturing at least a first glass structure of the first glass structures to extend from the at least the first interior surface of the at least the first wall and into the first cavity; wherein manufacturing the main glass body section comprises manufacturing at least a second glass structure of the second glass structures to extend from the at least the second interior surface of the at least the second wall and into the second cavity; wherein manufacturing the top glass lid comprises manufacturing at least a third glass structure of the third glass structures to extend from the at least the third interior surface of the top glass lid and into the first cavity; wherein manufacturing the top glass lid comprises manufacturing at least a fourth glass structure of the fourth glass structures to extend from the at least the third interior surface of the top glass lid and into the second cavity; wherein manufacturing the bottom glass lid comprises manufacturing at least a fifth glass structure of the fifth glass structures to extend from the at least the fourth interior surface of the bottom glass lid and into the first cavity; and wherein manufacturing the bottom glass lid comprises manufacturing at least a sixth glass structure of the sixth glass structures to extend from the at least the fourth interior surface of the bottom glass lid and into the second cavity.

Example 39 includes the method of any of Examples 37-38, further comprising: manufacturing an Alkali reaction chamber within the main glass body section; manufacturing an Alkali reservoir within the main glass body section; manufacturing a top photonic integrated circuit (PIC); positioning the top PIC above the top glass lid to interface with an input coupling laser and an output probe laser; manufacturing a bottom PIC; positioning the bottom PIC below the bottom glass lid to interface with an input probe laser; bonding the bottom glass lid to the main glass body section by at least one of anodic bonding, direct bonding, or eutectic bonding; bonding the top glass lid to the main glass body section by at least one of anodic bonding, direct bonding, or eutectic bonding; attaching the top PIC to the top glass lid with optical epoxy; and attaching the bottom PIC to the bottom glass lid with optical epoxy.

Example 40 includes the method of any of Examples 37-39, further comprising: manufacturing an Alkali reaction chamber within the main glass body section; manufacturing an Alkali reservoir within the main glass body section; manufacturing a top photonic integrated circuit (PIC); positioning the top PIC above the top glass lid to interface with an input coupling laser and an output probe laser; manufacturing a bottom PIC; positioning the bottom PIC below the bottom glass lid to interface with an input probe laser; manufacturing a top glass including at least one top surface comprising seventh glass structures extending at least one of away from or toward the at least one top surface; manufacturing a bottom glass including at least one bottom surface comprising eighth glass structures extending at least one of away from or toward the at least one bottom surface; manufacturing ninth glass structures onto at least one outer surface of the main glass body section, the ninth glass structures extending at least one of away from or toward the at least one outer surface of the main glass body section; positioning the top glass above the top PIC such that the seventh glass structures extend away from the first cavity and the second cavity; positioning the bottom glass below the bottom PIC such that the eighth glass structures extend away from the first cavity and the second cavity; bonding the bottom glass lid to the main glass body section by at least one of anodic bonding, direct bonding, or eutectic bonding; bonding the top glass lid to the main glass body section by at least one of anodic bonding, direct bonding, or eutectic bonding; attaching the top PIC to the top glass lid with optical epoxy; attaching the bottom PIC to the bottom glass lid with optical epoxy; attaching the top glass to the top PIC with optical epoxy; attaching the bottom glass to the bottom PIC with optical epoxy; and wherein the seventh glass structures, the eighth glass structures, and the ninth glass structures are configured to tune the index of refraction of the vapor cell to reduce RF signal scattering within the vapor cell.

What is claimed is:

1. A vapor cell, comprising:
a main glass body section comprising at least one wall surrounding a cavity, the at least one wall having at least a first interior surface having first glass structures extending at least one of into or away from the cavity;
a top glass lid positioned on top of and attached to the main glass body section, the top glass lid having at least a second interior surface having second glass structures extending at least one of into or away from the cavity;
a bottom glass lid positioned below and attached to the main glass body section, the bottom glass lid having at least a third interior surface having third glass structures extending at least one of into or away from the cavity; and
wherein the first glass structures, the second glass structures, and the third glass structures are configured to tune an index of refraction of the vapor cell to reduce RF signal scattering within the vapor cell.

2. The vapor cell of claim 1, wherein at least a first glass structure of the first glass structures extends from the at least the first interior surface of the at least one wall and into the cavity;
wherein at least a second glass structure of the second glass structures extends from the at least the second interior surface of the top glass lid and into the cavity; and
wherein at least a third glass structure of the third glass structures extends from the at least the third interior surface of the bottom glass lid and into the cavity.

3. The vapor cell of claim 1, wherein at least a first glass structure of the first glass structures extends away from the cavity as a void into the at least the first interior surface of the at least one wall;
wherein at least a second glass structure of the second glass structures extends away from the cavity as a void into the at least the second interior surface of the top glass lid; and
wherein at least a third glass structure of the third glass structures extends away from the cavity as a void into the at least the third interior surface of the bottom glass lid.

4. The vapor cell of claim 1, wherein the bottom glass lid is bonded to the main glass body section by at least one of anodic bonding, direct bonding, or eutectic bonding; and
wherein the top glass lid is bonded to the main glass body section by at least one of anodic bonding, direct bonding, or eutectic bonding.

5. The vapor cell of claim 1, further comprising:
wherein the at least one wall of the main glass body section includes four walls positioned in a rectangular shape; and
wherein the at least the first interior surface includes four interior surfaces including an interior surface for each of the four walls positioned in the rectangular shape.

6. The vapor cell of claim 1, further comprising:
an Alkali reaction chamber positioned within the main glass body section;
an Alkali reservoir positioned within the main glass body section;
a top photonic integrated circuit (PIC) positioned above the top glass lid, the top PIC interfacing with an input coupling laser, an output probe laser, and at least a first photodiode; and
a bottom PIC positioned below the bottom glass lid, the bottom PIC interfacing with an input probe laser and at least a second photodiode.

7. The vapor cell of claim 6, further comprising:
wherein the top glass lid is bonded to the main glass body section by at least one of anodic bonding, direct bonding, or eutectic bonding;
wherein the bottom glass lid is bonded to the main glass body section by at least one of anodic bonding, direct bonding, or eutectic bonding;
wherein the top PIC is attached to the top glass lid with optical epoxy; and
wherein the bottom PIC is attached to the bottom glass lid with optical epoxy.

8. The vapor cell of claim 1, further comprising:
an Alkali reaction chamber positioned within the main glass body section;
an Alkali reservoir positioned within the main glass body section;
a top photonic integrated circuit (PIC) positioned above the top glass lid, the top PIC interfacing with an input coupling laser and an output probe laser;
a bottom PIC positioned below the bottom glass lid, the bottom PIC interfacing with an input probe laser;
a top glass positioned above the top PIC, the top glass including at least one top surface having fourth glass structures extending at least one of away from or toward the cavity;
a bottom glass positioned below the bottom PIC, the bottom glass including at least one bottom surface having fifth glass structures extending at least one of away from or toward the cavity;
wherein the main glass body section includes at least one outer surface having sixth glass structures extending at least one of away from or toward the cavity; and
wherein the fourth glass structures, the fifth glass structures, and the sixth glass structures are configured to tune the index of refraction of the vapor cell to reduce the RF signal scattering within the vapor cell.

9. The vapor cell of claim 8, further comprising:
wherein the top glass lid is bonded to the main glass body section by at least one of anodic bonding, direct bonding, or eutectic bonding;
wherein the bottom glass lid is bonded to the main glass body section by at least one of anodic bonding, direct bonding, or eutectic bonding;
wherein the top PIC is attached to the top glass lid with optical epoxy;
wherein the bottom PIC is attached to the bottom glass lid with optical epoxy;
wherein the top glass is attached to the top PIC with optical epoxy; and
wherein the bottom glass is attached to the bottom PIC with optical epoxy.

10. The vapor cell of claim 1, further comprising:
wherein the main glass body section further comprises at least a second wall surrounding a second cavity, the at least the second wall having at least a fourth interior surface having fourth glass structures extending at least one of into or away from the second cavity;
wherein the at least the second interior surface of the top glass lid has fifth glass structures extending at least one of into or away from the second cavity;
wherein the at least the third interior surface of the bottom glass lid has sixth glass structures extending at least one of into or away from the second cavity; and
wherein the fourth glass structures, the fifth glass structures, and the sixth glass structures are configured to tune the index of refraction of the vapor cell to reduce the RF signal scattering within the vapor cell.

11. The vapor cell of claim 10, further comprising:
at least one Alkali reaction chamber positioned within the main glass body section;
at least one Alkali reservoir positioned within the main glass body section;
a top photonic integrated circuit (PIC) positioned above the top glass lid, the top PIC interfacing with an input coupling laser and an output probe laser;
a bottom PIC positioned below the bottom glass lid, the bottom PIC interfacing with an input probe laser;
a top glass positioned above the top PIC, the top glass including at least one top surface having seventh glass structures extending at least one of away from or toward the cavity and the second cavity;
a bottom glass positioned below the bottom PIC, the bottom glass including at least one bottom surface having eighth glass structures extending at least one of away from or toward the cavity and the second cavity;
wherein the main glass body section includes at least one outer surface having ninth glass structures extending at least one of away from or toward the cavity; and
wherein the seventh glass structures, the eighth glass structures, and the ninth glass structures are configured to tune the index of refraction of the vapor cell to reduce the RF signal scattering within the vapor cell.

12. The vapor cell of claim 11, further comprising:
at least one meandering channel connecting the at least one Alkali reaction chamber, the at least one Alkali reservoir, the first cavity, and the second cavity.

13. A vapor cell, comprising:
a main glass body section comprising at least one wall surrounding a cavity, the at least one wall having at least a first interior surface having first glass structures extending at least one of into or away from the cavity;
a top glass lid positioned on top of and attached to the main glass body section, the top glass lid having at least a second interior surface having second glass structures extending at least one of into or away from the cavity, wherein the top glass lid is bonded to the main glass body section by at least one of anodic bonding, direct bonding, or eutectic bonding;
a bottom glass lid positioned below and attached to the main glass body section, the bottom glass lid having at least a third interior surface having third glass structures extending at least one of into or away from the cavity, wherein the bottom glass lid is bonded to the main glass body section by at least one of anodic bonding, direct bonding, or eutectic bonding;
an Alkali reaction chamber positioned within the main glass body section;
an Alkali reservoir positioned within the main glass body section;
a top photonic integrated circuit (PIC) positioned above the top glass lid, the top PIC interfacing with an input coupling laser and an output probe laser, wherein the top PIC is attached to the top glass lid with optical epoxy;
a bottom PIC positioned below the top glass lid, the bottom PIC interfacing with an input probe laser, wherein the bottom PIC is attached to the bottom glass lid with optical epoxy;
a top glass positioned above the top PIC, the top glass including at least one top surface having fourth glass structures extending at least one of away from or toward the cavity, wherein the top glass is attached to the top PIC with optical epoxy;
a bottom glass positioned below the bottom PIC, the bottom glass including at least one bottom surface having fifth glass structures extending at least one of away from or toward the cavity, wherein the bottom glass is attached to the bottom PIC with optical epoxy;
wherein the main glass body section includes at least one outer surface having sixth glass structures extending at least one of away from or toward the cavity; and
wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

14. The vapor cell of claim 13, wherein at least a first glass structure of the first glass structures extends from the at least the first interior surface of the at least one wall and into the cavity;
wherein at least a second glass structure of the second glass structures extends from the at least the second interior surface of the top glass lid and into the cavity;
wherein at least a third glass structure of the third glass structures extends from the at least the third interior surface of the bottom glass lid and into the cavity;
wherein at least a fourth glass structure of the fourth glass structures extends from the at least one top surface of the top glass away from the cavity; and
wherein at least a fifth glass structure of the fifth glass structures extends from the at least one bottom surface of the bottom glass away from the cavity.

15. The vapor cell of claim 13, wherein at least a first glass structure of the first glass structures extends away from the cavity as a void into the at least the first interior surface of the at least one wall;
wherein at least a second glass structure of the second glass structures extends away from the cavity as a void into the at least the second interior surface of the top glass lid;
wherein at least a third glass structure of the third glass structures extends away from the cavity as a void into the at least the third interior surface of the bottom glass lid;
wherein at least a fourth glass structure of the fourth glass structures extends toward the cavity as a void into the at least one top surface of the top glass; and
wherein at least a fifth glass structure of the fifth glass structures extends toward the cavity as a void into the at least one bottom surface of the bottom glass.

16. The vapor cell of claim 13, further comprising:
wherein the main glass body section further comprises at least a second wall surrounding a second cavity, the at least the second wall having at least a fourth interior surface having seventh glass structures extending at least one of into or away from the second cavity;
wherein the at least the second interior surface of the top glass lid has eighth glass structures extending at least one of into or away from the second cavity;
wherein the at least the third interior surface of the bottom glass lid has ninth glass structures extending at least one of into or away from the second cavity;
wherein the third glass structures, the fourth glass structures, and the ninth glass structures are configured to tune the index of refraction of the vapor cell to reduce the RF signal scattering within the vapor cell.

17. A vapor cell, comprising:
a main glass body section comprising:
at least a first wall surrounding a first cavity, the at least the first wall having at least a first interior surface having first glass structures extending at least one of into or away from the first cavity;
at least a second wall surrounding a second cavity, the at least the second wall having at least a second interior surface having second glass structures extending at least one of into or away from the second cavity;
a top glass lid positioned on top of and attached to the main glass body section, the top glass lid having at least a third interior surface having third glass structures extending at least one of into or away from the first cavity and fourth glass structures extending at least one of into or away from the second cavity, wherein the top glass lid is bonded to the main glass body section;
a bottom glass lid positioned below and attached to the main glass body section, the bottom glass lid having at least a fourth interior surface having fifth glass structures extending at least one of into or away from the first cavity and sixth glass structures extending at least one of into or away from the second cavity, wherein the bottom glass lid is bonded to the main glass body section;
wherein the first glass structures, the second glass structures, the third glass structures, the fourth glass structures, the fifth glass structures, and the sixth glass structures are configured to tune an index of refraction of the vapor cell to reduce RF signal scattering within the vapor cell.

18. The vapor cell of claim 17, wherein at least a first glass structure of the first glass structures extends from the at least the first interior surface of the at least the first wall and into the first cavity;
wherein at least a second glass structure of the second glass structures extends from the at least the second interior surface of the at least the second wall and into the second cavity;
wherein at least a third glass structure of the third glass structures extends from the at least the third interior surface of the top glass lid and into the first cavity;
wherein at least a fourth glass structure of the fourth glass structures extends from the at least the third interior surface of the top glass lid and into the second cavity;
wherein at least a fifth glass structure of the fifth glass structures extends from the at least the fourth interior surface of the bottom glass lid and into the first cavity; and
wherein at least a sixth glass structure of the sixth glass structures extends from the at least the fourth interior surface of the bottom glass lid and into the second cavity.

19. The vapor cell of claim 17, further comprising:
an Alkali reaction chamber positioned within the main glass body section;
an Alkali reservoir positioned within the main glass body section;
a top photonic integrated circuit (PIC) positioned above the top glass lid, the top PIC interfacing with an input coupling laser and an output probe laser;
a bottom PIC positioned below the bottom glass lid, the bottom PIC interfacing with an input probe laser;
wherein the top PIC is attached to the top glass lid with optical epoxy; and
wherein the bottom PIC is attached to the bottom glass lid with optical epoxy.

20. The vapor cell of claim 19, further comprising:
a top glass positioned above the top PIC, the top glass including at least one top surface having seventh glass structures extending at least one of away from or toward the first cavity and the second cavity;
a bottom glass positioned below the bottom PIC, the bottom glass including at least one bottom surface having eighth glass structures extending at least one of away from or toward the first cavity and the second cavity;
wherein the main glass body section includes at least one outer surface having ninth glass structures extending at least one of away from or toward the first cavity and the second cavity; and
wherein the seventh glass structures, the eighth glass structures, and the ninth glass structures are configured to tune the index of refraction of the vapor cell to reduce the RF signal scattering within the vapor cell.
